(19) United States
(12) Patent Application Publication
(10) Pub. No.: US 2026/0247875 A1
(43) Pub. Date: Aug. 20, 2026

(54) HEAT-FLOW CONTROLLED PHASE CHANGE MATERIAL DEVICE WITH SIDEWALL LINERS AND METHODS FOR FORMING THE SAME

(71) Applicant: Taiwan Semiconductor Manufacturing Company Limited, Hsinchu (TW)

(72) Inventors: Hung-Ju LI, Hsinchu (TW); Kuo-Pin CHANG, Zhubei City (TW); Chang-Chih HUANG, Taichung (TW); Yu-Wei TING, Taipei City (TW); Chih-Ren HSIEH, Changhua City (TW); Kuo-Ching HUANG, Hsinchu (TW); Harry-Hak-Lay CHUANG, Zhubei City (TW)

(21) Appl. No.: 19/055,579

(22) Filed: Feb. 18, 2025

(51) Int. Cl. H10N 70/20; H10B 63/00; H10B 63/10; H10N 70/00

(52) U.S. Cl. CPC H10N 70/231; H10B 63/10; H10B 63/30; H10N 70/021; H10N 70/063; H10N 70/066; H10N 70/841; H10N 70/8613

(57) ABSTRACT

A device structure may be formed by: forming bottom electrodes and heater elements within a dielectric material layer; forming layer stacks of a respective bottom liner, a respective phase change material portion, and a respective top electrode; and forming sidewall liners on layer stacks, wherein each contiguous combination of a respective one of the bottom electrodes, a respective one of the heater elements, a respective one of the layer stack, and a respective sidewall liner selected from the sidewall liners constitutes a phase change memory cell, whereby a plurality of phase change memory cells is formed. A first subset of the plurality of phase change memory cells is configured to generate a first temperature gradient along a first lateral direction.

### BACKGROUND

Phase change material (PCM) devices may be used for memory-based computing applications due to their scalability and non-volatility. Thermal cross-talk between phase change memory cells undermines performance and scalability, particularly as device miniaturization progresses. Additionally, stress-induced reliability issues arise from thermal and mechanical stress during operation to limit the long-term stability of the PCM devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of an intermediate embodiment structure after formation of field effect transistors, metal interconnect structures, and dielectric material layers according to an embodiment of the present disclosure.

FIG. 2 is a vertical cross-sectional view of the intermediate embodiment structure after formation of via cavities through a dielectric material layer according to an embodiment of the present disclosure.

FIG. 3 is a vertical cross-sectional view of the intermediate embodiment structure after formation of metal via structures according to an embodiment of the present disclosure.

FIG. 4 is a vertical cross-sectional view of the intermediate embodiment structure after formation of bottom electrodes and heater cavities according to an embodiment of the present disclosure.

FIG. 5 is a vertical cross-sectional view of the intermediate embodiment structure after lateral expansion of heater cavities according to an embodiment of the present disclosure.

FIG. 6 is a vertical cross-sectional view of the intermediate embodiment structure after formation of heater elements according to an embodiment of the present disclosure.

FIG. 7 is a vertical cross-sectional view of the intermediate embodiment structure after formation of a continuous layer stack including a bottom liner layer, a phase change material layer comprising a phase change material, and a top electrode material layer according to an embodiment of the present disclosure.

FIG. 8 is a vertical cross-sectional view of the intermediate embodiment structure after patterning the continuous layer stack into in-process layer stacks each including an in-process bottom liner, an in-process phase change material portion, and an in-process top electrode according to an embodiment of the present disclosure.

FIG. 9 is a vertical cross-sectional view of the intermediate embodiment structure after formation of a sidewall liner layer according to an embodiment of the present disclosure.

FIG. 10 is a vertical cross-sectional view of the intermediate embodiment structure after formation of in-process sidewall liners according to an embodiment of the present disclosure.

FIG. 11 is a vertical cross-sectional view of the intermediate embodiment structure after patterning the in-process layer stacks into layer stacks each including a bottom liner, a phase change material portion, and a top electrode and patterning the in-process sidewall liners into sidewall liners according to an embodiment of the present disclosure.

FIG. 12 is a vertical cross-sectional view of the embodiment structure after removal of a patterned etch mask layer according to an embodiment of the present disclosure.

FIG. 13A-13C illustrate sequential top-down views of a region of a first configuration of the embodiment structure during the processing steps of FIG. 10-12.

FIG. 14A-14C illustrate sequential top-down views of a region of a second configuration of the embodiment structure during the processing steps of FIG. 10-12.

FIG. 15A-15C illustrate sequential top-down views of a region of a third configuration of the embodiment structure during the processing steps of FIG. 10-12.

FIG. 16 illustrates a top-down view of a region of a fourth configuration of the embodiment structure after the processing steps of FIG. 10.

FIG. 17A-17C illustrate sequential top-down views of regions of fifth, sixth, seventh, and eighth configurations of the embodiment structure during the processing steps of FIG. 10-12.

FIG. 18A-18C illustrate sequential top-down views of regions of ninth, tenth, eleventh, and twelfth configurations of the embodiment structure during the processing steps of FIG. 10-12.

FIGS. 19A, 19B, 19C, and 19D are horizontal cross-sectional views thirteenth, fourteenth, fifteenth, and sixteenth configurations of the embodiment structure after the processing steps of FIG. 12.

FIG. 20 is a vertical cross-sectional view of the embodiment structure after formation of an encapsulation dielectric layer and additional metal interconnect structures according to an embodiment of the present disclosure.

FIG. 21A-21D are various configurations of a phase change material portion in various programmed resistance states according to an embodiment of the present disclosure.

FIG. 22A illustrates sequential vertical cross-sectional views of a phase change memory cell during programing into a low resistance state. FIG. 22B illustrates sequential vertical cross-sectional views of a phase change memory cell during programing into a first intermediate resistance state. FIG. 22C illustrates sequential vertical cross-sectional views of a phase change memory cell during programing into a second intermediate resistance state. FIG. 22D illustrates sequential vertical cross-sectional views of a phase change memory cell during programing into a high resistance state.

FIG. 23 illustrates pairs of a horizontal cross-sectional view and a vertical cross-sectional view for eight configurations of a phase change memory cell according to embodiments of the present disclosure.

FIG. 24 is a diagram comparing the sizes of the unit cell areas of the various configurations of the phase change memory cells of the present disclosure.

FIG. 25 is a vertical cross-sectional view of a first alternative configuration of the embodiment structure after formation of heater elements according to an embodiment of the present disclosure.

FIG. 26 is a vertical cross-sectional view of the first alternative configuration of the embodiment structure after formation of the encapsulation dielectric layer and the additional metal interconnect structures according to an embodiment of the present disclosure.

FIG. 27 is a vertical cross-sectional view of a second alternative configuration of the embodiment structure after formation of heater elements according to an embodiment of the present disclosure.

FIG. 28 is a vertical cross-sectional view of the second alternative configuration of the embodiment structure after formation of the encapsulation dielectric layer and the additional metal interconnect structures according to an embodiment of the present disclosure.

FIG. 29 is a first flowchart that illustrates general processing steps for manufacturing a device structure according to embodiments of the present disclosure.

FIG. 30 is a second flowchart that illustrates general processing steps for manufacturing a device structure according to embodiments of the present disclosure.

FIG. 31 is a third flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Phase change memory (PCM) devices have great promise for computation-in-memory (CIM) applications but face challenges such as resistance variations, drift in low-resistance and high-resistance states, as well as limitations in scalability and efficiency due to large cell sizes, narrow memory windows, and high write power. Various embodiments disclosed herein addresses these challenges by incorporating at least one sidewall liner and a bottom liner in the PCM cell design. The sidewall liner, may be formed on the sidewalls of the phase change material portion, controls the resistance of the high-resistance state, while the bottom liner may be positioned beneath the phase change material and above a heater element. These sidewall liners and bottom liners may interact with the amorphous volume of the phase change material to stabilize resistance drift, enabling accurate and reliable weight representation in CIM operations. Additionally, the resistance range may be expanded by adjusting the resistivity of the sidewall liner, such as by incorporating nitrogen or carbon atoms into its metallic composition. The design of the various embodiments disclosed herein may reduce power consumption, decreases cell size, and improve reliability, while providing enhanced performance and efficiency for modern CIM applications.

Embodiments of the present disclosure are directed to configurations of phase change memory cells configured to reduce thermal cross-talk and thermal stress. Embodiments of the present disclosure may be used to enhance the reliability and scalability of memory array arrays. In one aspect, the phase change memory cells of the present disclosure reduce thermal cross-talk between adjacent phase change memory cells. Thermal isolation zones, which are also referred to as thermal kick-out zones (KOZs), may be used to control the flow of heat generated during memory cell operation. The thermal isolation zones prevent thermal interference between neighboring phase change memory cells, thereby improving data integrity and operational reliability.

Embodiments of the present disclosure may be used to provide an adaptive memory cell architecture that supports multi-level memory functionality. Consistent resistance control for programmed states of the phase change memory cells may be provided through directional distribution of heat generated during the programming operations. Phase change memory cells having different geometries and/or providing different heat flow directions may be provided in multiple phase change memory arrays to minimize thermal stress at a die level, and to extend the lifetime of the phase change memory devices. The phase change memory cells having different heat flow characteristics may be manufactured using a same set of processing steps by modifying masking patterns that are used during patterning of the phase change memory cells. The various embodiments of the present disclosure are now described with reference to accompanying drawings.

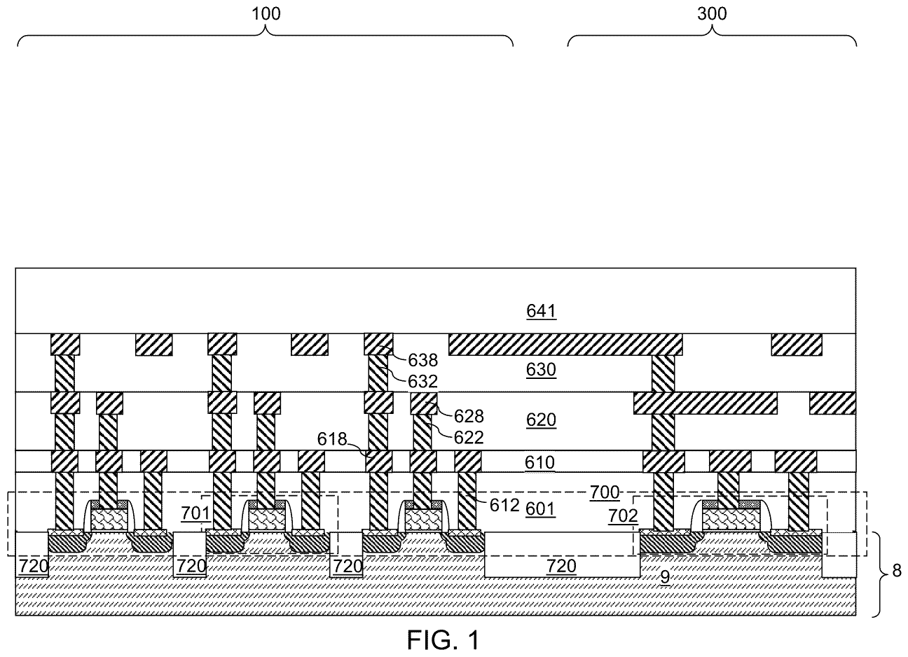

Referring to FIG. 1, an intermediate embodiment structure according to the present disclosure is illustrated. The intermediate embodiment structure includes a substrate 8, which may be a semiconductor substrate, such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720.

Semiconductor devices 700 may be formed on the semiconductor material layer 9. The semiconductor devices 700 may comprise complementary metal-oxide-semiconductor (CMOS) transistors and optionally additional semiconductor devices (such as resistors, diodes, capacitor structures, etc.). The semiconductor devices 700 may comprise programming transistors 701 that are formed in a memory array region 100, and peripheral transistors 702 that are formed in a peripheral region 300. Each field effect transistor (701, 702) may comprise a source region, a drain region, a channel region, a gate dielectric, and a gate electrode. In one embodiment, the channel region may comprise a portion of the semiconductor material layer 9, and may comprise a single crystalline semiconductor material. Each of the programming transistors 701 may be configured to provide a set of programming pulses for a respective phase change memory cell to be subsequently formed. The peripheral transistors 702 may be formed as components of a peripheral circuit that controls the operation of the programming transistors 701, and interfaces with an input/output (I/O) circuit (not illustrated).

In one embodiment, the substrate 8 may include a single crystalline silicon substrate, and the field effect transistors (701, 702) may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures embedded within dielectric material layers may be subsequently formed over the substrate 8 and the semiconductor devices. In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the semiconductor devices 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. An additional dielectric material layer, which is herein referred to as a lower fourth interconnect-level dielectric material layer 641 may be formed over the third interconnect-level dielectric material layer 630.

Each of the dielectric material layers (601, 610, 620, 630, 641) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure.

Generally, semiconductor devices (such as field effect transistors (701, 702)) may be formed on a substrate 8, and metal interconnect structures (612, 618, 622, 628, 632, 638) and dielectric material layers (601, 610, 620, 630, 641) over the semiconductor devices. The metal interconnect structures (612, 618, 622, 628, 632, 638) may be formed in the dielectric material layers (601, 610, 620, 630, 641), and may be electrically connected to the semiconductor devices.

In summary, programming transistors 701 may be formed on a substrate 8. Metal interconnect structures (612, 618, 622, 628, 632, 638) formed within interconnect-level dielectric material layers (601, 610, 620, 630, 641) may be formed over the programming transistors 701. The metal interconnect structures (612, 618, 622, 628, 632, 638) may be configured to be electrically connected to heater elements of phase change memory cells to be subsequently formed.

According to an aspect of the present disclosure, the programming transistors 701 may be configured to program a respective one of the phase change memory cells into at least two different resistive states, and preferably into at least three different resistive states, and more preferably into at least four different resistive states. The programming of each phase change memory cell into different resistive states may be effected by selecting a pulse pattern from a set of pre-programmed pulse patterns that each programming transistor 701 may apply. The pulse patterns may differ from one another by the duration of a pulse pattern and the peak voltage of the pulse pattern. In one embodiment, the total number of resistive states that a phase change memory cell may be programmed into may be in a range from 2 to 64, such as from 3 to 16, and/or from 4 to 8, although a greater number of resistive states may be programmed as needed by altering the pulse pattern that is generated from each programming transistor 701.

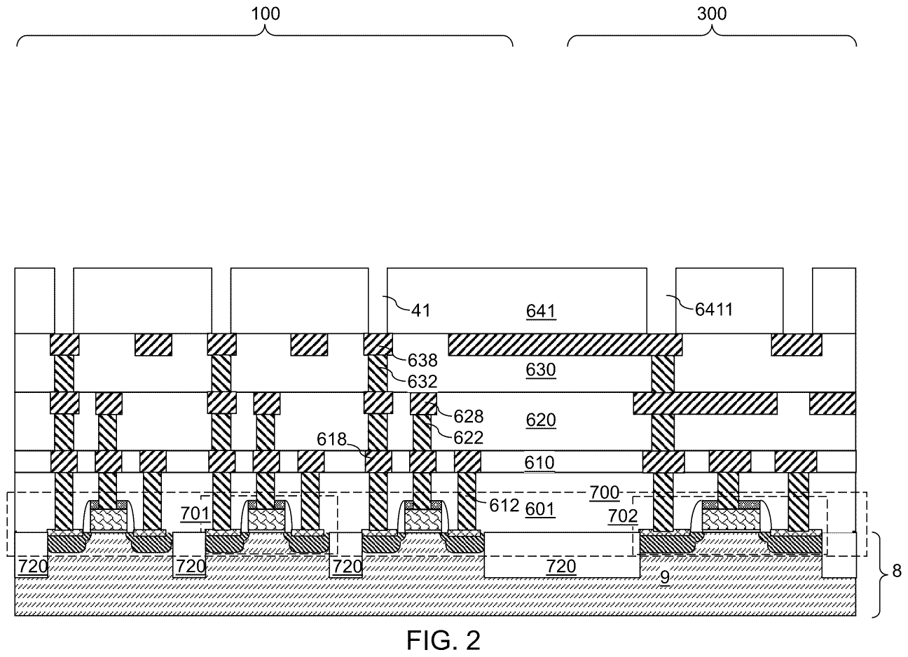

Referring to FIG. 2, via cavities 41 may be formed through a dielectric material layer (such as the lower fourth interconnect-level dielectric material layer 641). Each via cavity 41 may be formed over a respective one of the underlying metal interconnect structures (such as a subset of the third metal line structures 638) so that top surface segments of the underlying metal interconnect structures are physically exposed. The dielectric material layer, through which the via cavities 41 are formed, comprises a heat-resistant dielectric material such as undoped silicate glass or a doped silicate glass. The thickness of the dielectric material layer may be in a range from 200 nm to 1,000 nm, although lesser or greater thicknesses may also be used. The lateral dimension (such as the diameter) of each via cavity 41 may be in a range from 30 nm to 300 nm, although lesser or greater lateral dimensions may also be used. Peripheral via cavities 6411 may be formed through the dielectric material layer in the peripheral region 300.

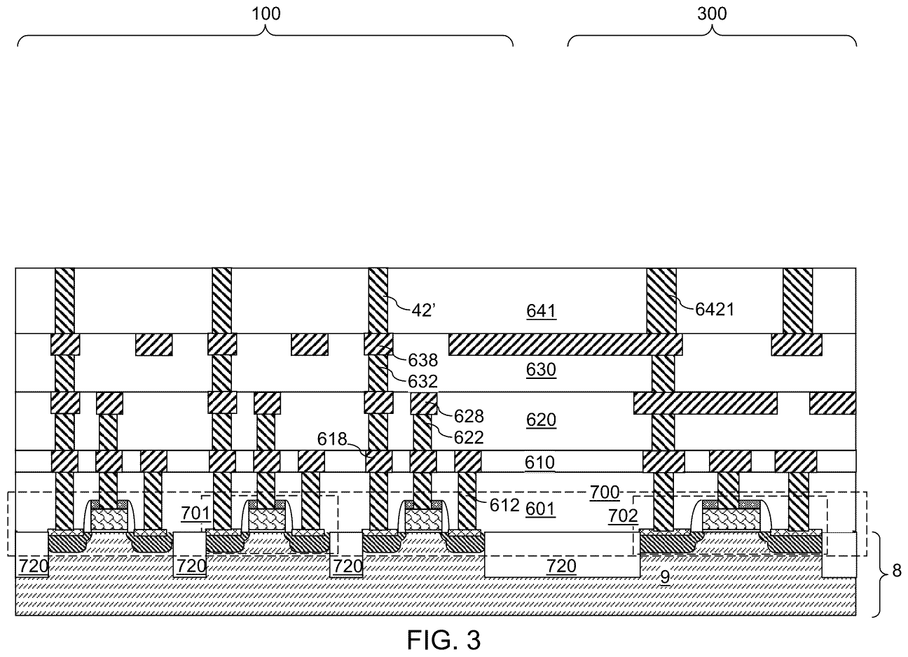

Referring to FIG. 3, a metallic fill material having a high electrical conductivity, such as copper or tungsten, may be deposited in the via cavities 41 and the peripheral via cavities 6411. A metallic liner material, such as a conductive metallic nitride material, may be optionally deposited as a thin liner prior to deposition of the metallic fill material. Excess portions of the metallic fill material may be removed from above the horizontal plane including the top surface of the dielectric material layer (such as the lower fourth interconnect-level dielectric material layer 641) by performing a planarization process, which may comprise a recess etch process and/or a chemical mechanical polishing process. Each remaining portion of the optional metallic liner material and the metallic fill material that fills a respective via cavity 41 constitutes an in-process bottom electrode 42′, which is subsequently modified to become a bottom electrode of a respective phase change memory cell. As used herein, an “in-process” element refers to an element that is subsequently modified structurally or compositionally. Each remaining portion of the optional metallic liner material and the metallic fill material that fills a peripheral via cavity 6411 constitutes a lower peripheral via structure 6421.

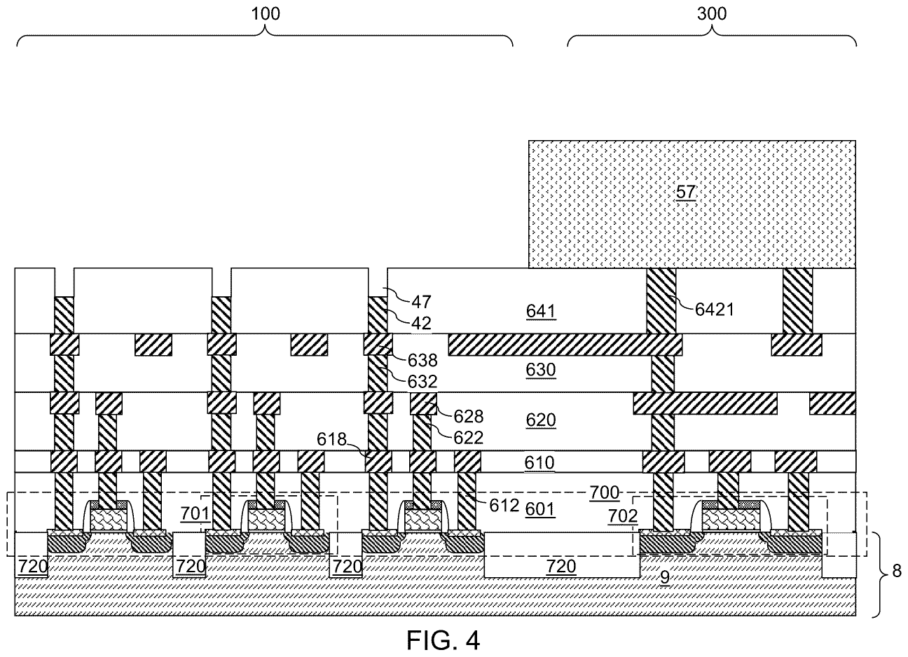

Referring to FIG. 4, a masking layer 57, such as a patterned photoresist layer, may be formed over the dielectric material layer (such as the lower fourth interconnect-level dielectric material layer 641) to cover the peripheral region 300 without covering the memory array region 100. A recess etch process may be performed to vertically recess the in-process bottom electrodes 42′ selectively to the material of the dielectric material layer, i.e., without removing the material of the dielectric material layer. The recess etch process may comprise a wet etch process or a reactive ion etch process. Upper portions of the in-process bottom electrodes 42′ may be removed by the recess etch process. Remaining portions of the in-process bottom electrodes 42′ constitute bottom electrodes 42 for the phase change memory cells to be subsequently formed. Heater cavities 47 may be formed in the volumes from which the upper portions of the in-process bottom electrodes 42′ may be removed. The height of the bottom electrodes 42 may be in a range from 100 nm to 800 nm, such as from 200 nm to 400 nm, although lesser or greater heights may also be used. The depth of the heater cavities 47 may be in a range from 100 nm to 800 nm, such as from 200 nm to 400 nm, although lesser or greater depths may also be used.

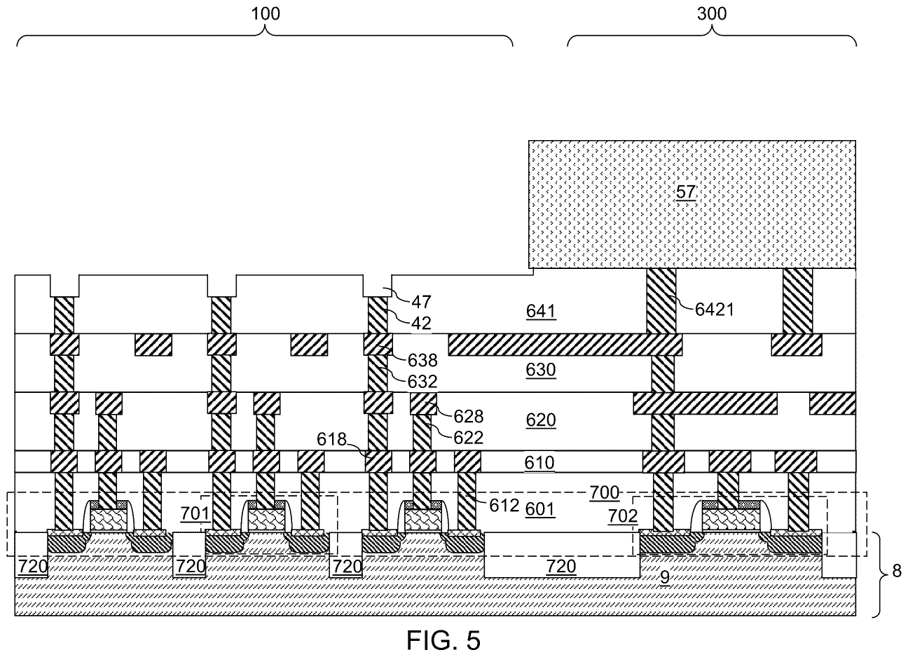

Referring to FIG. 5, an isotropic recess etch process may be performed to isotropically recess physically exposed surfaces of the dielectric material layer, which include sidewall surfaces of the heater cavities 47 and a planar top surface of the dielectric material layer. For example, in embodiments in which the dielectric material layer (such as the lower fourth interconnect-level dielectric material layer 641) comprises a silicate glass, the isotropic recess etch process may comprise a wet etch process using dilute hydrofluoric acid. The duration of the isotropic recess etch process may be selected such that the recess distance for the material of the dielectric material layer is in a range from 1 nm to 100 nm, such as from 5 nm to 50 nm, although lesser or greater recess distances may also be used. In this embodiment, the top surface of the dielectric material layer may have a step between the memory array region 100 and the peripheral region 300. In embodiments in which the isotropic recess etch process is performed, the heater cavities 47 may be laterally expanded. Generally, a metallic material to be subsequently deposited in the heater cavities 47 has a higher electrical resistivity than the metallic fill material of the bottom electrodes 42. The lateral expansion of heater cavities 47 may be advantageously used to optimize the electrical resistance of heater elements to be subsequently formed in the heater cavities 47. The masking layer 57 may be subsequently removed, for example, by ashing.

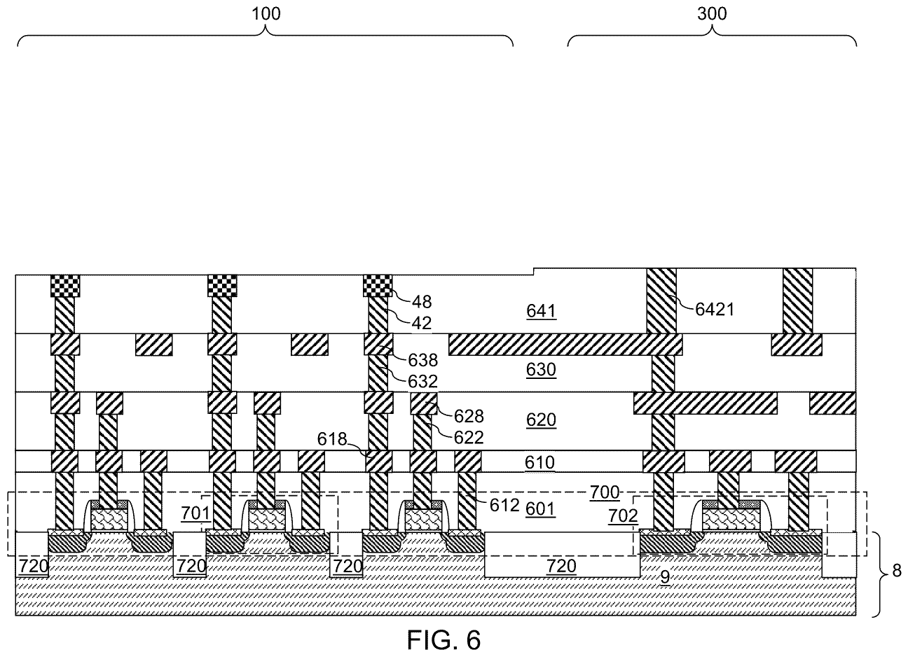

Referring to FIG. 6, a metallic heater material having higher electrical conductivity than the metallic fill material of the bottom electrodes 42 may be deposited in the heater cavities 47. The metallic heater material may comprise, and/or may consist essentially of, at least one metallic nitride material such as TiN, TaN, WN, and/or MoN. Other suitable metallic heater materials may be within the contemplated scope of disclosure. The metallic heater material may be deposited by chemical vapor deposition or physical vapor deposition. In one embodiment, the metallic heater material may comprise a stoichiometric or near-stoichiometric metallic nitride material, such as stoichiometric or near-stoichiometric TiN, TaN, WN, and/or MoN. If the heater cavities 47 have an aspect ratio (i.e., a height-to-width ratio) greater than 1, a conformal deposition process such as a chemical vapor deposition process may be used to deposit the metallic heater material.

A planarization process may be performed to remove portions of the metallic heater material that are deposited over the top surface of the dielectric material layer (such as the lower fourth interconnect-level dielectric material layer 641) that embeds the bottom electrodes 42. The planarization process may comprise a selective recess etch process that etches the metallic heater material selectively to the dielectric material of the dielectric material layer. Each remaining portion of the metallic heater material that fills a respective one of the heater cavities 47 constitutes a heater element 48. In one embodiment, top surface of the heater elements 48 may be coplanar with, or substantially coplanar with, the portion of the top surface of the dielectric material layer (such as the lower fourth interconnect-level dielectric material layer 641) located in the memory array region 100.

For each phase change memory cell to be subsequently formed, a bottom electrode 42 and a heater element 48 may be formed within a dielectric material layer (such as the lower fourth interconnect-level dielectric material layer 641). The heater element 48 is electrically connected to an electrical node (i.e., the output node) of a respective one of the programming transistors 701. In one embodiment, a two-dimensional array of stacks of a bottom electrode 42 and a heater element 48 may be formed in the memory array region 100.

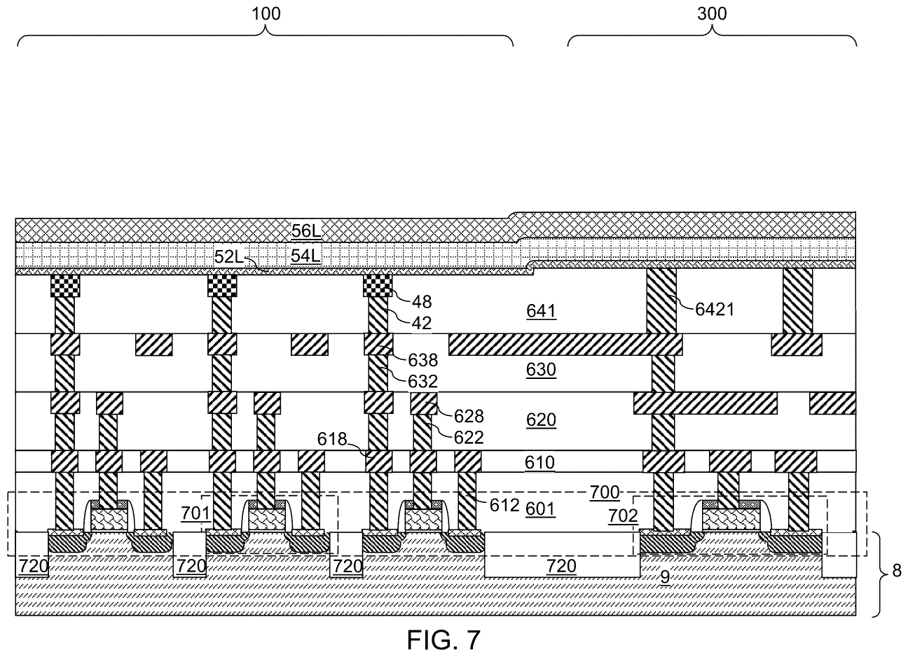

Referring to FIG. 7, a continuous layer stack (52L, 54L, 56L) including a bottom liner layer 52L, a phase change material layer 54L comprising a phase change material, and a top electrode material layer 56L may be sequentially deposited over the top surface of the dielectric material layer (such as the lower fourth interconnect-level dielectric material layer 641) that embeds the bottom electrodes 42 and the heater elements 48.

The bottom liner layer 52L comprises a first metallic nitride material, which may be a stoichiometric or near-stoichiometric metallic nitride material. For example, the bottom liner layer 52L may comprise TaN, TiN, WN, and/or MoN. In one embodiment, the electrical conductivity of the metallic material of the bottom liner layer 52L may be in a range from 1.0×10³ S/cm to 1.0×10⁵ S/cm. The thickness of the bottom liner layer 52L is selected such that patterned portions of the bottom liner layer 52L may provide electrical resistance during operation of phase memory cells to be subsequently formed. For example, the thickness of the bottom liner layer 52L may be in a range from 1 nm to 20 nm, such as from 2 nm to 4 nm, although lesser or greater thicknesses may also be used. The bottom liner layer 52L may be deposited by chemical vapor deposition or physical vapor deposition.

The phase change material layer 54L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. In one embodiment, the phase change material of the phase change material layer 54L may comprise a doped GST compound such as N-doped GST, Si-doped GST, C-doped GST, Ge-doped GST, Ru-doped GST, or Al-doped GST, or a doped GeTe compound such as N-doped GeTe, Si-doped GeTe, C-doped GeTe, or Ge-doped GeTe. The phase change material layer 54L may be deposited by physical vapor deposition. The thickness of the phase change material layer 54L may be in a range from 30 nm to 200 nm, such as from 50 nm to 90 nm, although lesser and greater thicknesses may also be used. In one embodiment, the phase change material of the phase change material layer may be selected such that the electrical conductivity of the amorphous phase of the phase change material is in a range from 1.0×10⁻⁸ S/cm to 1.0×10⁻³ S/cm, while the electrical conductivity of the crystalline phase of the phase change material is in a range from 1.0×10⁻¹ S/cm to 1.0×10³ S/cm.

The top electrode material layer 56L comprises a metallic material such as W, Ta, Ti, Mo, WN, TiN, WN, or MoN. The top electrode material layer 56L may have a thickness in a range from 100 nm to 200 nm, although lesser or greater thicknesses may also be used. The top electrode material layer 56L may be deposited by chemical vapor deposition or physical vapor deposition.

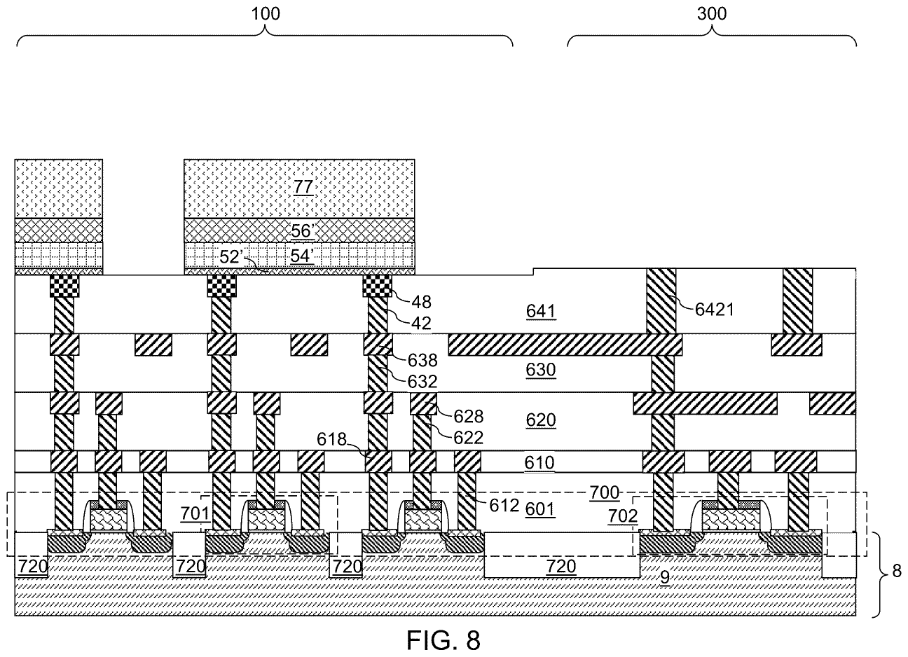

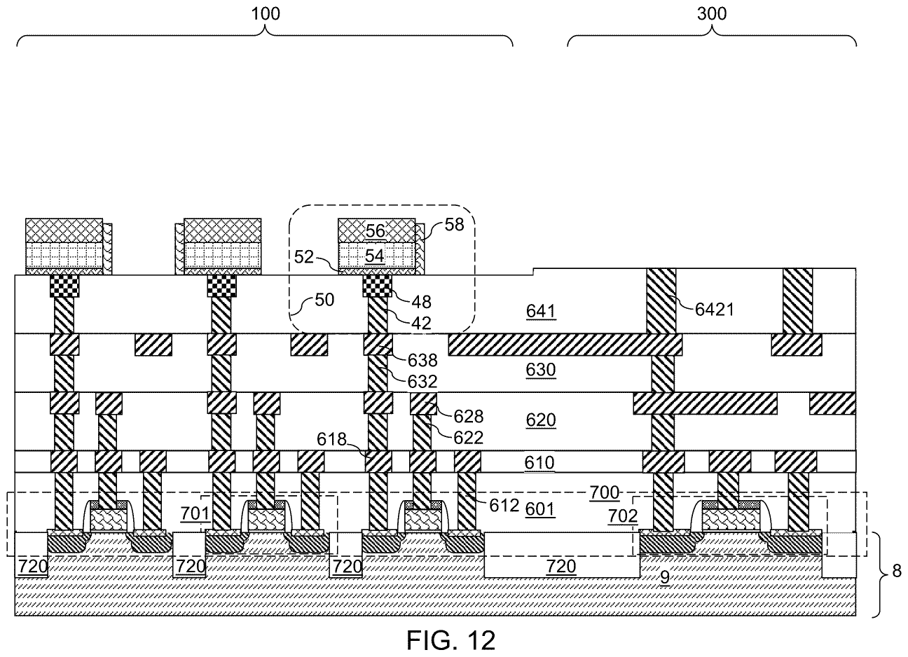

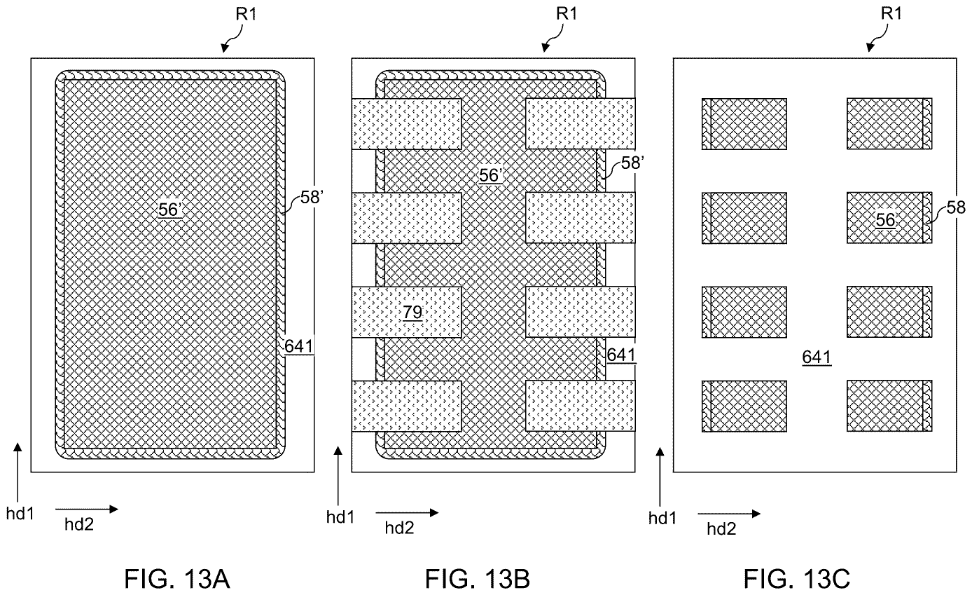

FIG. 8-19D collectively describe various configurations for phase change memory cells that may be formed on a same substrate 8. FIGS. 8, 9, 10, 11, and 12 illustrate a sequence of processing steps that may be used to form the phase change memory cells 50 (see FIG. 12) of the present disclosure. FIG. 13A-19D illustrate various configurations of the phase change memory cells 50 that may be formed on the substrate 8. FIG. 13A-19D illustrate sixteen configurations for the phase change memory cells 50 of the present disclosure. According to an aspect of the present disclosure, the embodiment structure of the present disclosure includes at least one of the sixteen configurations illustrated in FIG. 13A-19D, and preferably includes at least two of the sixteen configuration illustrated in FIG. 13A-19D.

Thus, the various configurations of the phase change memory cells 50 of the present disclosure do not constitute distinct species that must be manufactured separately, but may be manufactured simultaneously on a same substrate 8. Preferably, two or more configurations of the sixteen configurations of the phase change memory cells 50 of the present disclosure may be manufactured on a same substrate 8 within a single semiconductor die, and the benefits of the multiple configurations of the phase change memory cells 50 may be leveraged by manufacturing the multiple configurations of the phase change memory cells 50 on a same substrate 50. To reiterate, each configuration selected from the sixteen configurations of the phase change memory cells 50 may, or may not, be formed on a substrate 8, provided that at least one configuration of the phase change memory cells 50 is formed on the substrate 8. Thus, a total of 2¹⁶−1 possibilities are expressly contemplated, which covers the possibility of presence or absence of each of the sixteen configurations of the phase change memory cells 50 of the present disclosure except the possibility of absence of all sixteen configurations. Preferably, the embodiments in which two or more of the sixteen configurations of the phase change memory cells 50 are preferred. The number of such instances is 2¹⁶−1−16, which corresponds to the total combinations of presence or absence of each of the 16 configurations, less the configuration in which all 16 configurations are absent, less the instances in which only a single configuration is present. In one illustrative example, an embodiment structure including 16 types of phase change memory arrays each including a respective configuration of the phase change memory cells is expressly contemplated, in which each of the 16 configurations of the phase change memory cells is present within a respective one of the phase change memory arrays.

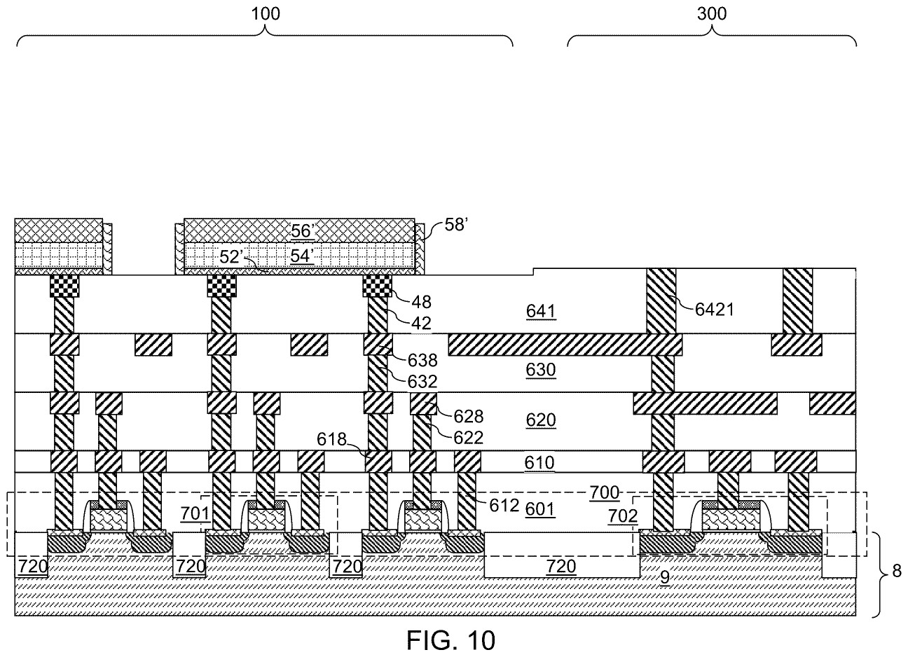

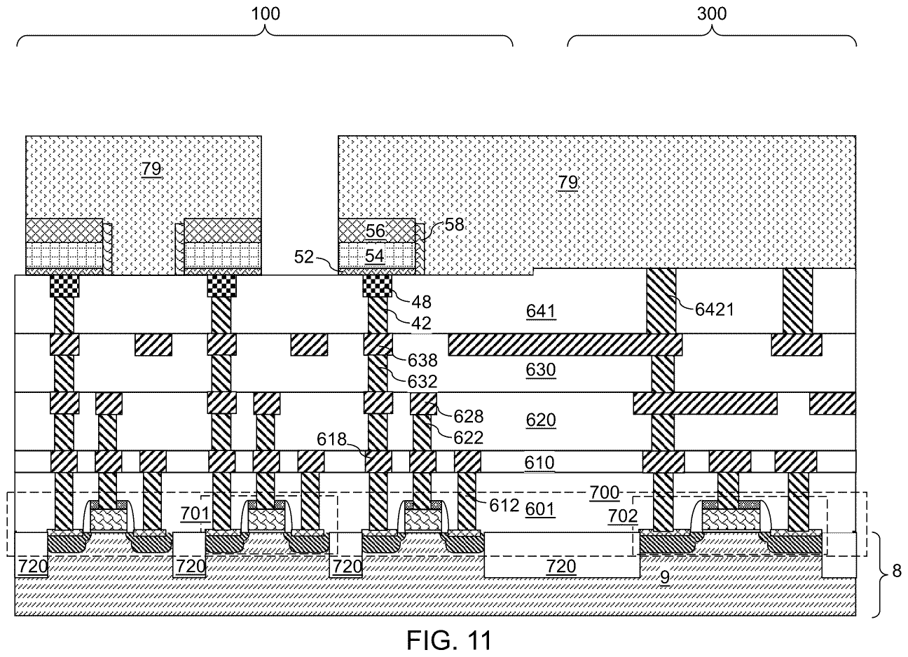

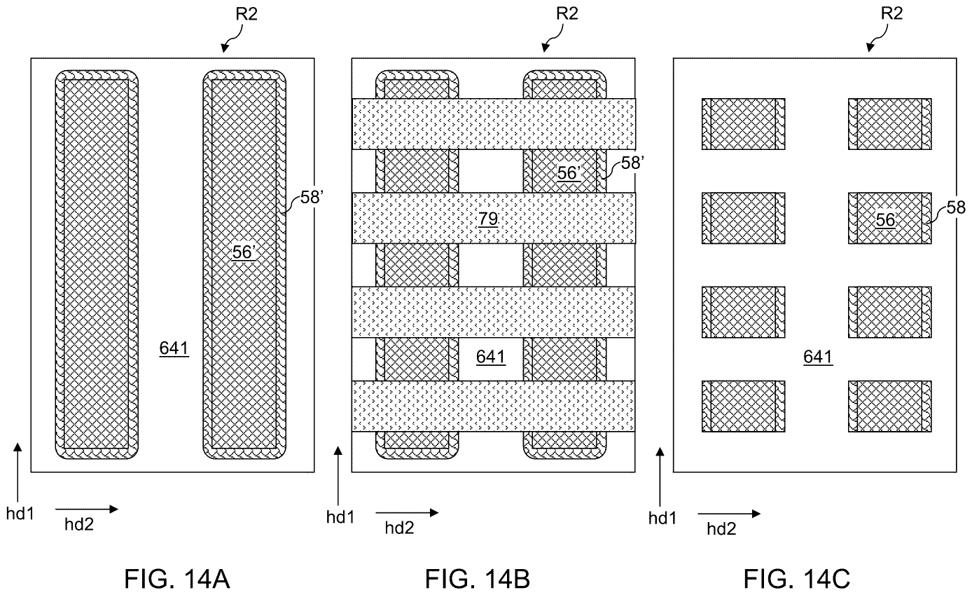

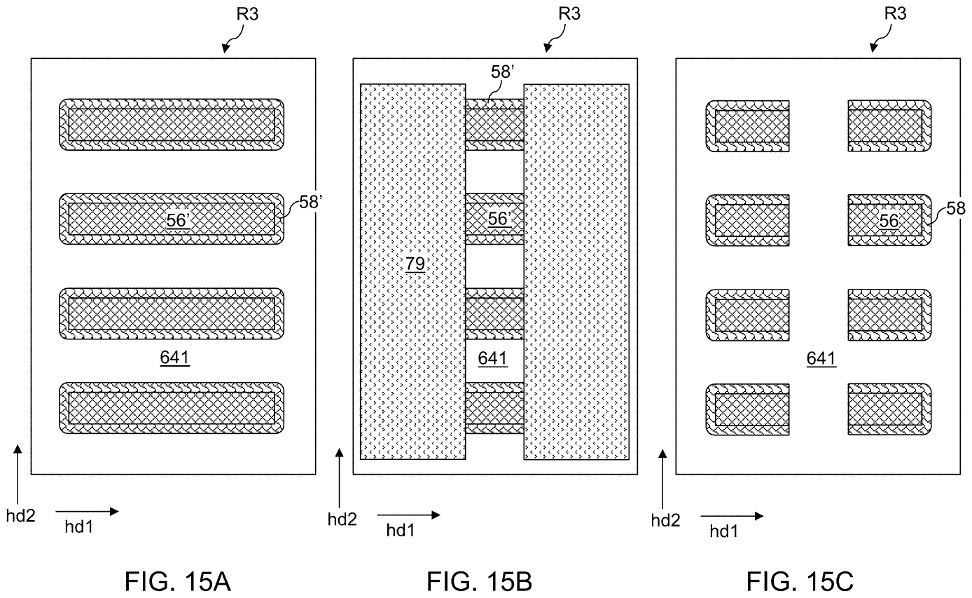

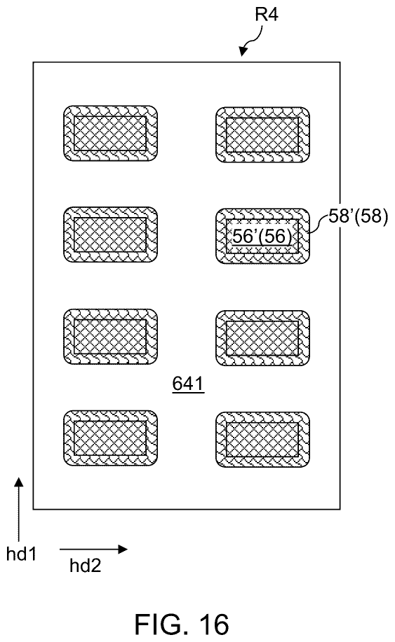

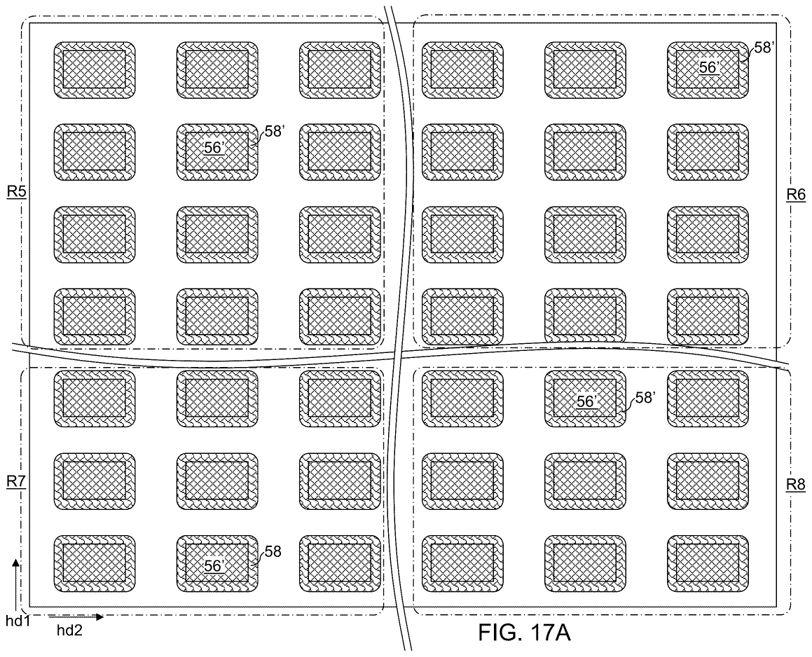

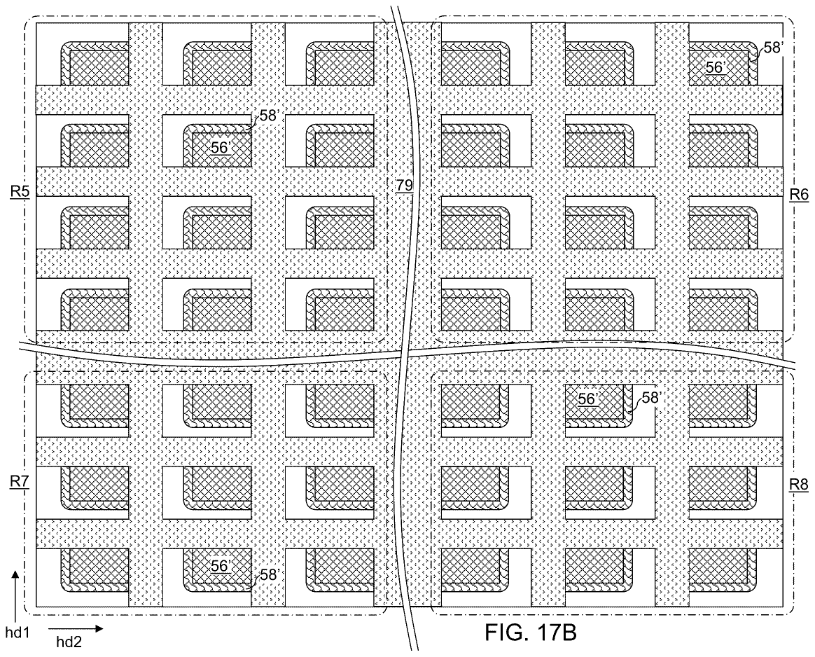

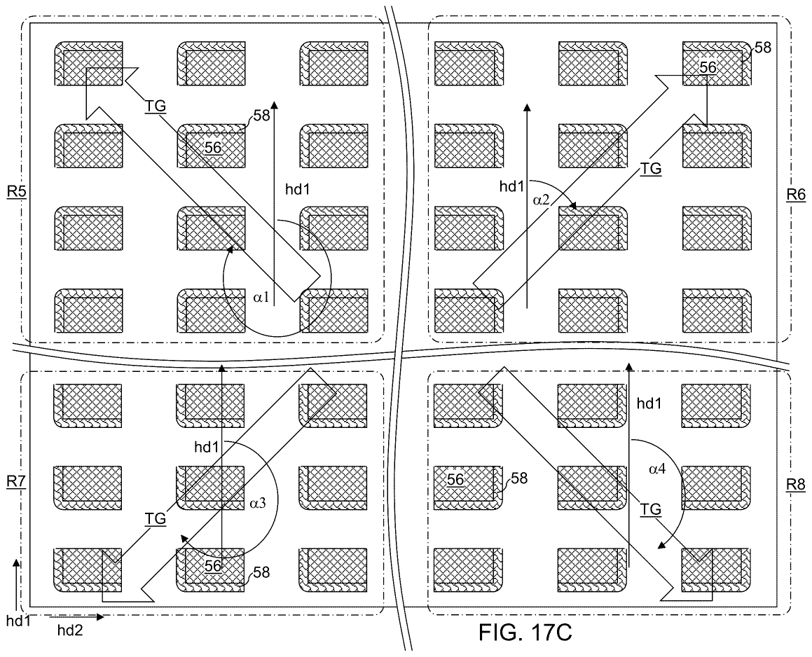

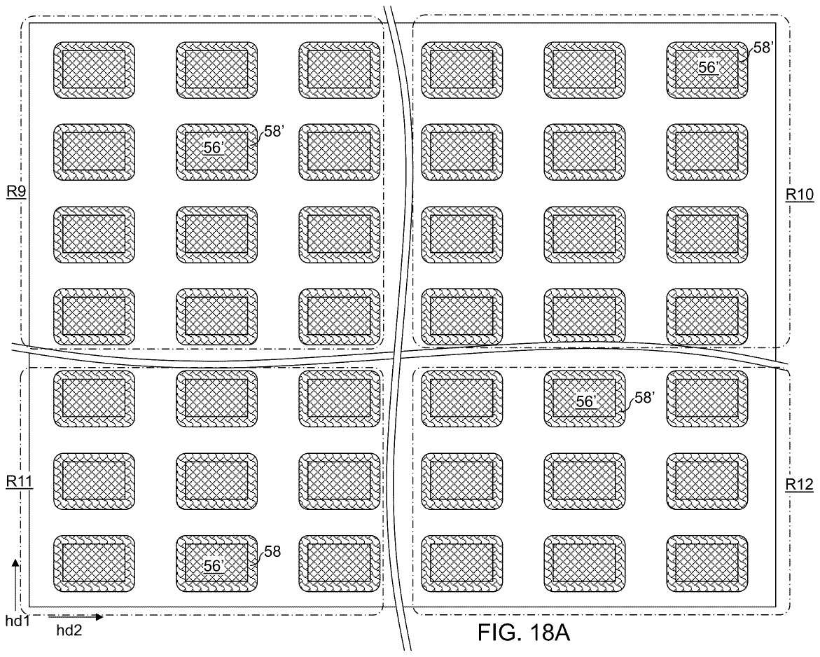

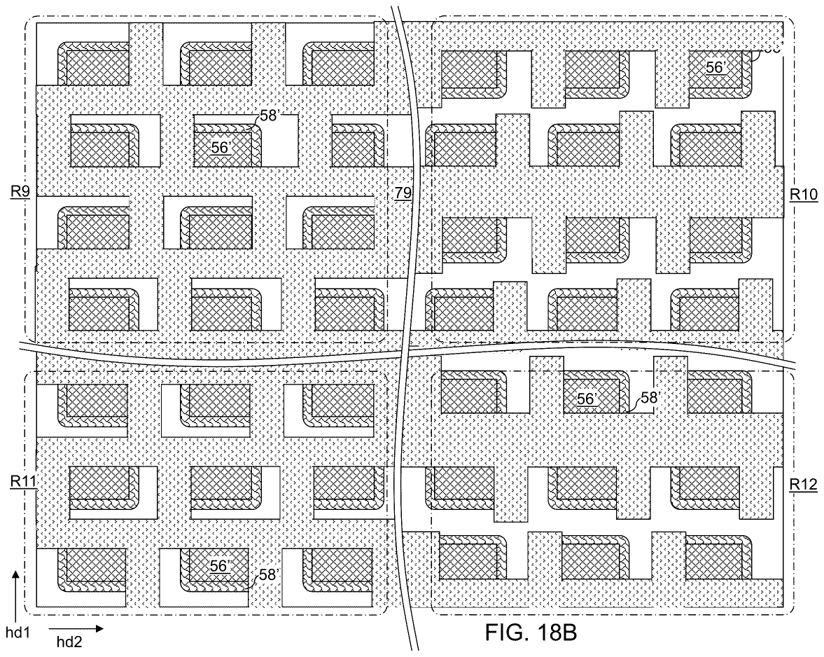

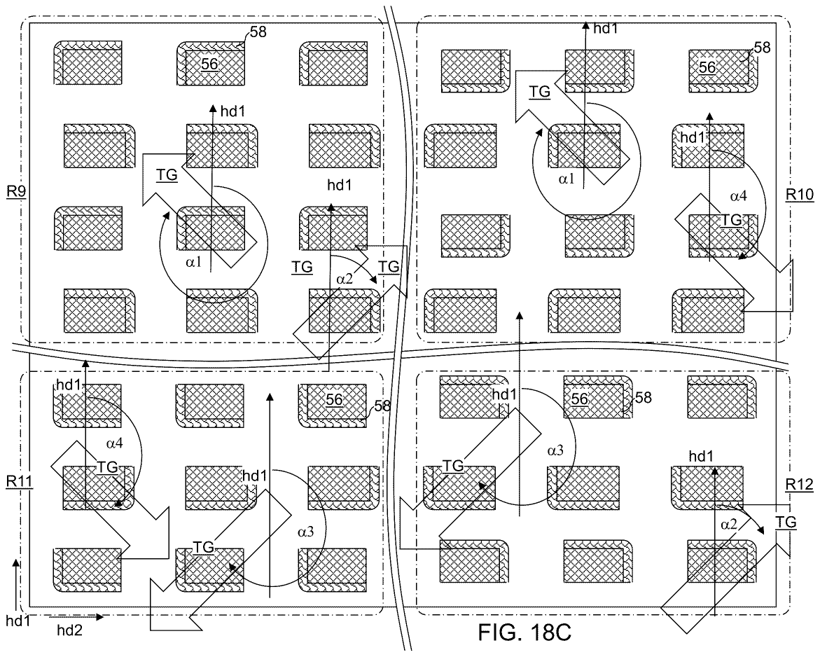

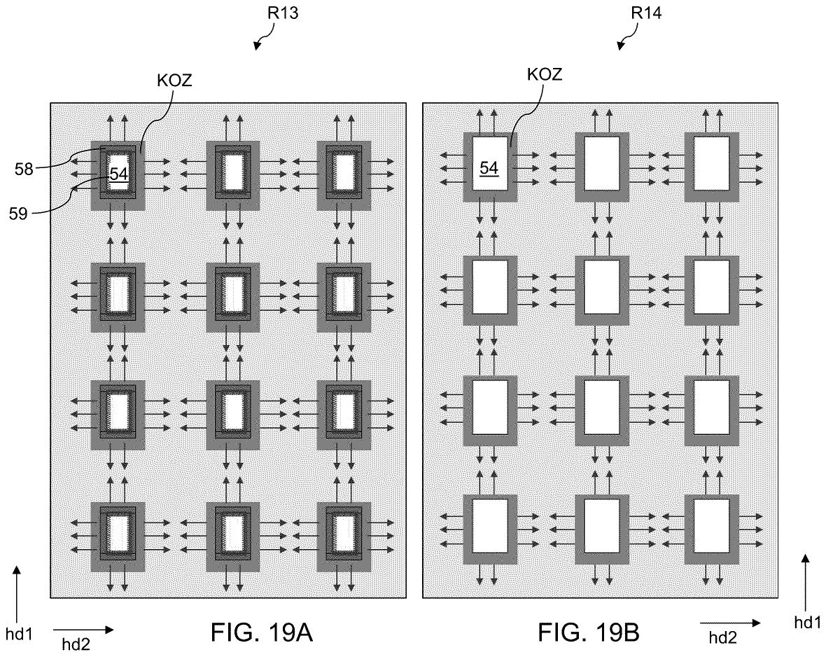

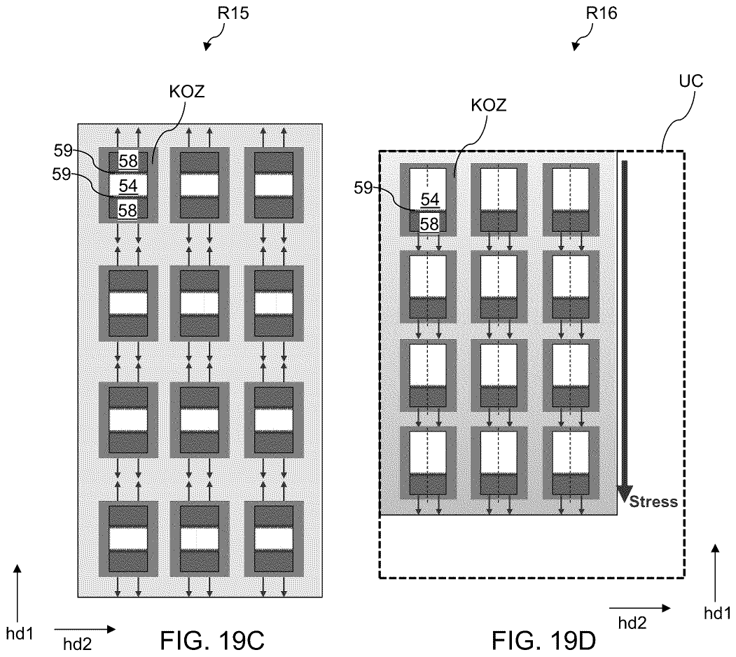

FIG. 13A-13C illustrate sequential top-down views of a region of a first configuration of the embodiment structure during the processing steps of FIG. 10-12. FIG. 14A-14C illustrate sequential top-down views of a region of a second configuration of the embodiment structure during the processing steps of FIG. 10-12. FIG. 15A-15C illustrate sequential top-down views of a region of a third configuration of the embodiment structure during the processing steps of FIG. 10-12. FIG. 16 illustrates a top-down view of a region of a fourth configuration of the embodiment structure after the processing steps of FIG. 10. The fourth configuration may be obtained by covering the entire device area including instances of the fourth configuration of the phase change memory cells 50 with a second patterned etch mask layer 79 (which is subsequently described with reference to FIG. 11). FIG. 17A-17C illustrate sequential top-down views of regions of fifth, sixth, seventh, and eighth configurations of the embodiment structure during the processing steps of FIG. 10 12. FIG. 18A-18C illustrate sequential top-down views of regions of ninth, tenth, eleventh, and twelfth configurations of the embodiment structure during the processing steps of FIG. 10-12. FIGS. 19A, 19B, 19C, and 19D are horizontal cross-sectional views thirteenth, fourteenth, fifteenth, and sixteenth configurations of the embodiment structure after the processing steps of FIG. 12.

Referring to FIG. 8, a first patterning process may be performed to pattern the continuous layer stack (52L, 54L, 56L) into in-process layer stacks (52′, 54′, 56′). Specifically, a first patterned etch mask layer 77 may be formed over the continuous layer stack (52L, 54L, 56L). For example, the first patterned etch mask layer 77 may be formed by applying a photoresist layer over the continuous layer stack (52L, 54L, 56L), and lithographically patterning the photoresist layer into an array of discrete patterned photoresist material portions. In one embodiment, the first patterned etch mask layer 77 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape. In one embodiment, the lateral dimensions of each patterned photoresist material portion may be selected to provide patterning of at least two phase change memory cells in subsequent processing steps. Alternatively, the lateral dimensions of each patterned photoresist material portion may be selected to provide patterning of a single phase change memory cell in subsequent processing steps.

A first anisotropic etch process may be performed to etch portions of the continuous layer stack (52L, 54L, 56L) that are not masked by the first patterned etch mask layer 77. The first anisotropic etch process has an etch chemistry that etches the materials of the continuous layer stack (52L, 54L, 56L) selectively to the material of the dielectric material layer (such as the lower fourth interconnect-level dielectric material layer 641) that embeds the heater elements 48. The continuous layer stack (52L, 54L, 56L) is patterned into in-process layer stacks (52′, 54′, 56′) each including an in-process bottom liner 52′, an in-process phase change material portion 54′, and an in-process top electrode 56′. As used herein, an “in-process” element refers to an element that is structurally and/or compositionally modified in a subsequent processing step. Each in-process bottom liner 52′ is a patterned portion of the bottom liner layer 52L. Each in-process phase change material portion 54′ is a patterned portion of the phase change material layer 54L. Each in-process top electrode 56′ is a patterned portion of the top electrode material layer 56L. For each in-process layer stack (52′, 54′, 56′), the sidewalls of the in-process bottom liner 52′ may be vertically coincident with the sidewalls of the in-process phase change material portion 54′, and may be vertically coincident with the sidewalls of the in-process top electrode 56′. As used herein, a first surface is “vertically coincident” with a second surface in which the second surface overlies or underlies the first surface and in which the first surface and the second surface are located within a same vertical plane, which may be planar or curved in a horizontal cross-sectional view. The first patterned etch mask layer 77 may be subsequently removed, for example, by ashing or dissolution.

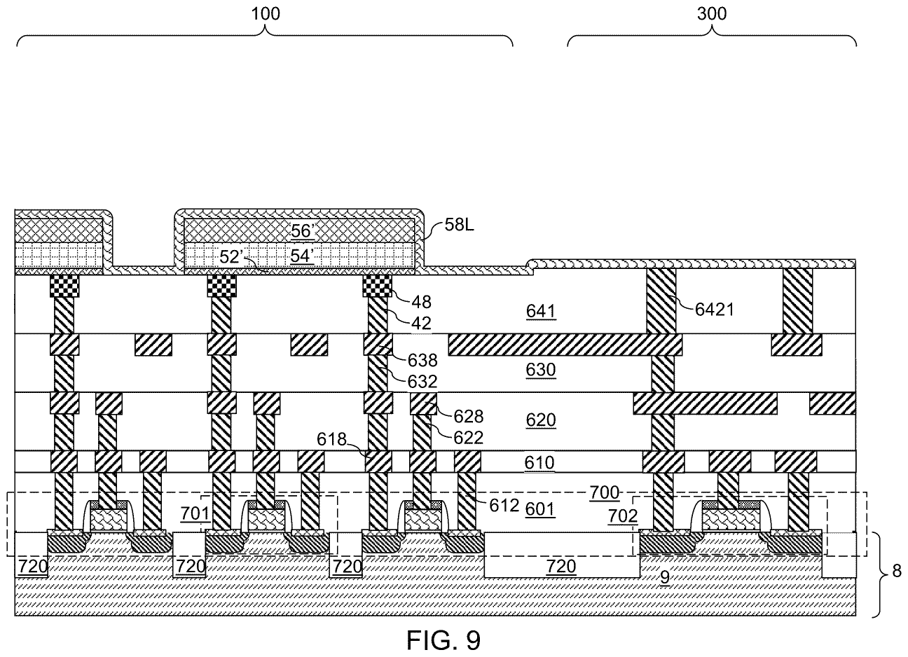

Referring to FIG. 9 and according to an aspect of the present disclosure, a sidewall liner layer 58L may be deposited on the physically exposed surfaces of the in-process layer stacks (52′, 54′, 56′) and on the physically exposed top surface of the dielectric material layer (such as the lower fourth interconnect-level dielectric material layer 641) that embeds the bottom electrodes 42 and the heater elements 48. In one embodiment, the sidewall liner layer 58L may comprise a metallic nitride material layer that is deposited by a conformal deposition process such as a chemical vapor deposition process. In one embodiment, the sidewall liner layer 58L may comprise a second metallic nitride material, which may comprise, and/or may consist essentially of, TiN, TaN, WN, and/or MoN. The thickness of the sidewall liner layer 58L may be in a range from 1 nm to 20 nm, such as from 2 nm to 4 nm, although lesser or greater thicknesses may also be used.

According to an aspect of the present disclosure, the electrical conductivity of the second metallic nitride material may be reduced by incorporating carbon atoms or nitrogen atoms into the metallic nitride material layer by in-situ doping or ex-situ doping of carbon atoms or nitrogen atoms, i.e., incorporation of the carbon atoms or the nitrogen atoms during deposition of the sidewall liner layer 58L or after deposition of the sidewall liner layer 58L. For example, the carbon atoms or the nitrogen atoms may be provided by a reactive carbon-containing gas (such as acetylene or ethylene) or a reactive nitrogen-containing gas (such as ammonia) during a chemical vapor deposition that deposits the sidewall liner layer 58L. Alternatively, the sidewall liner layer 58L may be exposed to an ambient containing reactive carbon-containing species or reactive nitrogen-containing species at an elevated temperature after the deposition process that deposits the sidewall liner layer 58L. Yet alternatively, an ion implantation process or a plasma doping process may be performed after the deposition process that deposits the sidewall liner layer 58L.

The carbon atoms or the nitrogen atoms are incorporated into the second metallic nitride material of the sidewall liner layer 58L at an atomic concentration such that the electrical conductivity of the doped metallic nitride material of the sidewall liner layer 58L after incorporation of the carbon atoms or the nitrogen atoms is less than ⅓ of the electrical conductivity of the second metallic nitride material prior to the incorporation of the carbon atoms or the nitrogen atoms. In an illustrative example, the electrical conductivity of the sidewall liner layer 58L after incorporation of the carbon atoms or the nitrogen atoms may be in a range from 1.0×10¹ S/cm to 1.0×10⁵ S/cm.

Generally, the ratio of the metal atoms to nitrogen atoms in a stoichiometric metallic compound MN, in which M is Ta, Ti, Mo, or W, is 1:1. In embodiments in which nitrogen doping is used, upon doping of a stoichiometric metallic compound with nitrogen atoms to form the sidewall liner layer 58L of the present disclosure, the ratio of the metal atoms to nitrogen atoms in the sidewall liner layer 58L may be in a range from 1:1.02 to 1:1.05. In embodiments in which carbon doping is used, upon doping of a stoichiometric metallic compound with carbon atoms to form the sidewall liner layer 58L of the present disclosure, the ratio of the metal atoms to nitrogen atoms to carbon atoms in the sidewall liner layer 58L may be in a range from 1:1:0.02 to 1:1:0.05. Generally, the atomic concentration of the extra nitrogen atoms in a nitrogen-doped metallic nitride material may be in a range from 0.02 times the atomic concentration of the metal atoms to 0.05 times the atomic concentration of the metal atoms. Likewise, the atomic concentration of the carbon atoms in a carbon-doped metallic nitride material may be in a range from 0.02 times the atomic concentration of the metal atoms to 0.05 times the atomic concentration of the metal atoms.

In one embodiment, the second metallic nitride material of the sidewall liner layer 58L after the doping process may have an electrical conductivity that is less than ⅓, and preferably less than 1/10, of an electrical conductivity of the first metallic nitride material of the in-process bottom liners 52′. In other words, the in-process bottom liners 52′ comprise a material having an electrical conductivity that is at least 3 times, and preferably at least 10 times, the electrical conductivity of the sidewall liner material of the sidewall liner layer 58L.

Generally, the first metallic nitride material of the bottom liner layer 52L (and of the in-process bottom liners 52′) and the second metallic nitride material (which is a doped metallic nitride material) of the sidewall liner layer 58L are selected such that the resistance of a bottom liner to be patterned from an in-process bottom liner 52′ and the resistance of a sidewall liner to be patterned from the sidewall liner layer 58L dominate the resistance of states of phase memory material cells having high resistance values, which include the high resistance state and intermediate resistance states having relatively high resistance values. In this embodiment, the resistance of the amorphous volume of a phase change material portion does not determine the resistance of high resistance states of a phase change memory cell. Thus, the phase change memory cell may operate without significant degradation caused by any resistance drift of a phase change material.

Referring to FIG. 10, an anisotropic etch process may be performed to remove horizontally-extending portions of the sidewall liner layer 58L. The anisotropic etch process may be selective to the material of the dielectric material layer (such as the lower fourth interconnect-level dielectric material layer 641) having formed therein the heater elements 48. Each remaining vertically-extending portion of the sidewall liner layer 58L constitutes an in-process sidewall liner 58′ that laterally surrounds a respective in-process layer stack (52′, 54′, 56′). Each in-process sidewall liner 58′ contacts each sidewall of the in-process bottom liner 52′, the in-process phase change material portion 54′, and the in-process top electrode 56′ of a respective in-process layer stack (52′, 54′, 56′). In one embodiment, an upper surface segment of each sidewall of the in-process top-electrodes 56′ may be physically exposed. Generally, an in-process sidewall liner 58′ may be formed around each in-process layer stack (52′, 54′, 56′) by conformally depositing and anisotropically etching a layer of the sidewall liner material.

Referring to FIG. 11, a second patterning process may be performed to pattern the in-process layer stacks (52′, 54′, 56′) and the in-process sidewall liners 58′. A second patterned etch mask layer 79 may be formed over the in-process layer stacks (52′, 54′, 56′) and the in-process sidewall liners 58′ in a manner that covers first areas of the in-process layer stacks (52′, 54′, 56′) and the in-process sidewall liners 58′ without covering second areas of the in-process layer stacks (52′, 54′, 56′) and the in-process sidewall liners 58′. For example, a photoresist layer (not shown) may be applied over the in-process layer stacks (52′, 54′, 56′) and the in-process sidewall liners 58′, and may be lithographically patterned into a two-dimensional array, such as a rectangular array, of patterned photoresist material portions. In one embodiment, the second patterned etch mask layer 79 may cover at least two discrete areas of each in-process layer stack (52′, 54′, 56′) that are not interconnected, i.e., separated by a gap that is not covered by the second patterned etch mask layer 79.

A second anisotropic etch process may be performed to etch unmasked portions of the in-process layer stacks (52′, 54′, 56′) and the in-process sidewall liners 58′, i.e., to etch the portions of the in-process layer stacks (52′, 54′, 56′) and the in-process sidewall liners 58′ that are not masked by the second patterned etch mask layer 79. The second anisotropic etch process has an etch chemistry that etches the materials of the in-process layer stacks (52′, 54′, 56′) and the in-process sidewall liners 58′ selectively to the material of the dielectric material layer (such as the lower fourth interconnect-level dielectric material layer 641) embedding the heater elements 48.

In one embodiment, the second patterning process may pattern each contiguous combination of an in-process layer stacks (52′, 54′, 56′) and an in-process sidewall liners 58′ into multiple discrete material portions that are not adjoined to one another. In one embodiment, each patterned portion of an in-process layer stack (52′, 54′, 56′) comprises a respective layer stack including a bottom liner 52, a phase change material portion 54, and a top electrode 56. Each patterned portion of an in-process sidewall liner 58′ constitutes a sidewall liner 58 according to an embodiment of the present disclosure. An in-process layer stacks (52′, 54′, 56′) may be patterned into a plurality of layer stacks (52, 54, 56). An in-process sidewall liner 58′ may be patterned into a plurality of sidewall liners 58. For each layer stack (52, 54, 56), the lateral distance between a sidewall of the layer stack (52, 54, 56) and a proximal sidewall of an underlying heater element 48 may be in a range from 30 nm to 200 nm, such as from 50 nm to 150 nm, although lesser or greater lateral distances may also be used.

Generally, at least one sidewall liner 58 may be formed on a sidewall of each layer stack (52, 54, 56), which is a patterned portion of the continuous layer stack (52L, 54L, 56L), by depositing and patterning a sidewall liner material. The sidewall liner material of the at least one sidewall liner 58 comprises a material having an electrical conductivity that is higher than an electrical conductivity of an amorphous phase of the phase change material. The sidewall liner material may comprise a metallic nitride material formed by incorporating carbon atoms or nitrogen atoms therein such that the metallic nitride material has a lower electrical conductivity than a stoichiometric metallic nitride material. Thus, in embodiments in which an amorphous phase portion of a phase change material and a sidewall liner 58 provide two parallel electrically conductive paths, the sidewall liner 58 provides a lower resistance path, and predominantly determines the total resistance of the two parallel electrically conductive paths during operation of the phase change memory cell of the present disclosure. This aspect is particularly useful for operation of the phase change memory cell for computation-in-memory (CIM) applications because the resistance drift effect of the phase change material is suppressed during operation of the phase change memory cell.

Referring to FIG. 12, the second patterned etch mask layer 79 may be removed, for example, by ashing. Each contiguous combination of a bottom electrode 42, a heater element 48, a bottom liner 52, a phase change material portion 54, a top electrode 56, and at least one sidewall liner 58 constitutes a phase change memory cell 50. A two-dimensional array of phase change memory cells 50 may be provided.

As discussed above, the first patterning process described with reference to FIG. 8 and the second patterning process described with reference to FIG. 11 may use various combinations of patterns to provide an array of phase change memory cells 50 having different configurations. FIG. 13A-13C illustrate sequential top-down views of a region of a first configuration of the embodiment structure during the processing steps of FIG. 10-12. FIG. 14A-14C illustrate sequential top-down views of a region of a second configuration of the embodiment structure during the processing steps of FIG. 10-12. FIG. 15A-15C illustrate sequential top-down views of a region of a third configuration of the embodiment structure during the processing steps of FIG. 10-12. FIG. 16 illustrates a top-down view of a region of a fourth configuration of the embodiment structure. FIG. 17A-17C illustrate sequential top-down views of regions of fifth, sixth, seventh, and eighth configurations of the embodiment structure during the processing steps of FIG. 10-12. FIG. 18A-18C illustrate sequential top-down views of regions of ninth, tenth, eleventh, and twelfth configurations of the embodiment structure during the processing steps of FIG. 10 12. FIGS. 19A, 19B, 19C, and 19D are horizontal cross-sectional views thirteenth, fourteenth, fifteenth, and sixteenth configurations of the embodiment structure after the processing steps of FIG. 12. The various configurations illustrated in FIG. 13A-19D are mere illustrations that describe specific configurations, and do not limit the scope of the present disclosure.

Referring collectively to FIG. 1-19D, bottom electrodes 42 and heater elements 48 are formed within a dielectric material layer (such as a lower fourth interconnect-level dielectric material layer 641), and in-process layer stacks (52′, 54′, 56′) of a respective in-process bottom liner 52′, a respective in-process phase change material portion 54′, and a respective in-process top electrode 56′ are formed over the heater elements 48. In-process sidewall liners 58′ are formed on the in-process layer stacks (52′, 54′, 56′), and the in-process layer stacks (52′, 54′, 56′) and the in-process sidewall liners 58′ are patterned. Patterned portions of the in-process layer stacks (52′, 54′, 56′) comprise layer stacks (52, 54, 56) of a respective bottom liner 52, a respective phase change material portion 54, and a respective top electrode 56. Patterned portions of the in-process sidewall liners 58′ comprise sidewall liners 58. The sidewall liners 58 are formed on layer stacks (52, 54, 56). Each contiguous combination of a respective one of the bottom electrodes 42, a respective one of the heater elements, a respective one of the layer stack (52, 54, 56), and a respective sidewall liner 58 selected from the sidewall liners 58 constitutes a phase change memory cell 50. A plurality of phase change memory cells 50 is formed, which may be arranged into phase change memory arrays including a respective periodic arrangement of a respective configuration of the phase change memory cells 50 of the present disclosure.

Referring to FIG. 13A, a region of a first configuration of the embodiment structure including an in-process layer stack (52′, 54′, 56′) and an in-process sidewall liner 58′ is illustrated at a processing step of FIG. 10. The first configuration may be located within a first device region R1 within the embodiment structure. The in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 13B, the region of the first configuration of the embodiment structure is illustrated after formation of the second patterned etch mask layer 79 and prior to performing the second anisotropic etch process. The second patterned etch mask layer 79 may comprise a two-dimensional array, such as a 2×N array, of patterned discrete etch mask material portions (such as patterned photoresist material portions) that cover 2N segments of the first sidewalls of the in-process layer stack (52′, 54′, 56′). In the illustrated example, the integer N is 4. Generally, the integer N may be any positive integer. As discussed above, the in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 13C, the second anisotropic etch process may be performed as described with reference to FIG. 11. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the first configuration illustrated in FIG. 13C, the at least one row of patterned portions may comprise two rows of patterned portions of the in-process layer stack (52′, 54′, 56′), i.e., two rows of layer stacks (52, 54, 56) that constitute a 2×N array of layer stacks (52, 54, 56). Generally, a P×Q array of in-process layer stacks (52′, 54′, 56′) may be used, and a 2P×QN array of phase change memory cells 50 may be formed by using the first configuration illustrated in FIG. 13A-13C.

Generally speaking, the at least one sidewall liner 58 may be formed on each layer stack (52, 54, 56) within each phase change memory cell 50. In the first configuration, the at least one sidewall liner 58 within each phase change memory cell 50 may consist of a single sidewall liner 58 that is formed directly on a sidewall of the layer stack (52, 54, 56) of the phase change memory cell 50, which is a patterned portion of the continuous layer stack (52L, 54L, 56L).

Referring to FIG. 14A, a region of a second configuration of the embodiment structure including two in-process layer stacks (52′, 54′, 56′) and two in-process sidewall liners 58′ is illustrated at a processing step of FIG. 10. The second configuration may be located within a second device region R2 within the embodiment structure. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 14B, the region of the second configuration of the embodiment structure is illustrated after formation of the second patterned etch mask layer 79 and prior to performing the second anisotropic etch process. The second patterned etch mask layer 79 may comprise a 1×N array of patterned discrete etch mask material portions (such as patterned photoresist material portions) that cover 2N segments of the first sidewalls of each in-process layer stack (52′, 54′, 56′). Each patterned discrete etch mask material portion may comprise a photoresist material strip that laterally extends along the second horizontal direction hd2 and having a uniform width along the first horizontal direction hd1. In the illustrated example, the integer N is 4. Generally, the integer N may be any positive integer. As discussed above, each in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 14C, the second anisotropic etch process may be performed as described with reference to FIG. 11. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the second configuration illustrated in FIG. 14C, the at least one row of patterned portions may comprise a row of patterned portions of the in-process layer stack (52′, 54′, 56′), i.e., a row of layer stacks (52, 54, 56) that constitutes a 1×N array of layer stacks (52, 54, 56). Generally, a P×Q array of in-process layer stacks (52′, 54′, 56′) may be used, and a P×QN array of phase change memory cells 50 may be formed by using the second configuration illustrated in FIG. 14A-14C.

Generally speaking, the at least one sidewall liner 58 may be formed on each layer stack (52, 54, 56) within each phase change memory cell 50. In the second configuration, the at least one sidewall liner 58 within each phase change memory cell 50 may comprise two sidewall liners 58 that are formed directly on a pair of sidewalls of the layer stack (52, 54, 56) of the phase change memory cell 50, which is a patterned portion of the continuous layer stack (52L, 54L, 56L). The pair of sidewalls may be parallel to each other, and the two sidewall liners 58 are laterally spaced apart from each other along a horizontal direction such as the second horizontal direction hd2.

Referring to FIG. 15A, a region of a third configuration of the embodiment structure including in-process layer stacks (52′, 54′, 56′) and in-process sidewall liners 58′ is illustrated at a processing step of FIG. 10. The third configuration may be located within a third device region R3 within the embodiment structure. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 15B, the region of the third configuration of the embodiment structure is illustrated after formation of the second patterned etch mask layer 79 and prior to performing the second anisotropic etch process. The second patterned etch mask layer 79 may comprise a pair of patterned discrete etch mask material portions (such as patterned photoresist material portions) that cover all second sidewalls of the in-process layer stacks (52′, 54′, 56′) and segments of each first sidewall that are adjoined to a respective second sidewall of the in-process layer stacks (52′, 54′, 56′). Each first sidewall of the in-process layer stacks (52′, 54′, 56′) comprises a central segment that is not covered by the second patterned etch mask layer 79. As discussed above, each in-process layer stack (52′, 54′, 56′) comprises first sidewalls that laterally extend along the first horizontal direction hd1 and second sidewalls that laterally extend along the second horizontal direction hd2. The two masking material portions of the second patterned etch mask layer 79 laterally extend along the second horizontal direction hd2, and may be laterally spaced apart from one another along the first horizontal direction hd1 so that central segments of each first sidewall of the in-process layer stacks (52′, 54′, 56′) are not covered by the second patterned etch mask layer 79.

Referring to FIG. 15C, the second anisotropic etch process may be performed as described with reference to FIG. 11. The second anisotropic etch process removes unmasked portions of the in-process layer stacks (52′, 54′, 56′) that are not covered by the second patterned etch mask layer 79. Each patterned portion of the in-process layer stacks (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the third configuration illustrated in FIG. 15C, the at least one row of patterned portions may comprise a row including two patterned portions of the in-process layer stack (52′, 54′, 56′), i.e., a row of layer stacks (52, 54, 56) that constitutes a 1×2 array of layer stacks (52, 54, 56). Generally, a P×Q array of in-process layer stacks (52′, 54′, 56′) may be used, and a P×2Q array of phase change memory cells 50 may be formed by using the third configuration illustrated in FIG. 15A-15C.

Generally speaking, the at least one sidewall liner 58 may be formed on each layer stack (52, 54, 56) within each phase change memory cell 50. In the third configuration, the at least one sidewall liner 58 within each phase change memory cell 50 may consist of a single sidewall liner 58 that is formed directly on three sidewalls of the layer stack (52, 54, 56) of the phase change memory cell 50, which is a patterned portion of the continuous layer stack (52L, 54L, 56L).

Referring to FIG. 16, a fourth configuration of the embodiment structure is illustrated after the processing steps of FIG. 10. The fourth configuration may be located within a fourth device region R4 within the embodiment structure. In the fourth configuration, the masking pattern of the first patterned etch mask layer 77 used at the processing steps of FIG. 8 is modified such that the pattern of the first patterned etch mask layer 77 is the same as the target pattern for an array of layer stacks (52, 54, 56) for an array of phase change memory cells 50. In this embodiment, the first anisotropic etch process described with reference to FIG. 8 patterns the continuous layer stack (52L, 54L, 56L) directly into the array of layer stacks (52, 54, 56). Further, upon performing the processing steps described with reference to FIGS. 9 and 10, the sidewall liner layer 58L may be patterned directly into the sidewall liners 58. The region of the fourth configuration of the embodiment structure may be entirely covered with the second patterned etch mask layer 79 during the processing steps of FIG. 11 so that no change occurs to the fourth configuration of the embodiment structure during the processing steps of FIGS. 11 and 12.

Generally speaking, the at least one sidewall liner 58 may be formed on each layer stack (52, 54, 56) within each phase change memory cell 50. In the fourth configuration, the at least one sidewall liner 58 within each phase change memory cell 50 may have an annular configuration. In other words, the at least one sidewall liner 58 within each phase change memory cell 50 may consist of a single sidewall liner 58 that is topologically homeomorphic to a torus, i.e., may be continuous deformed without formation of a new hole and without elimination of any pre-existing hole into a torus. The single sidewall liner 58 may be formed directly on each sidewall of a respective layer stack (52, 54, 56), which is a patterned portion of the continuous layer stack (52L, 54L, 56L).

According to an aspect of the present disclosure, phase change material portions 54 within a first subset of the layer stacks (52, 54, 56) comprises a respective sidewall facing a first outward surface normal direction (which may be parallel, antiparallel, or perpendicular to the first horizontal direction hd1 or the second horizontal direction hd2) having an azimuthal angle with respect to a first horizontal direction hd1 as measured along a clockwise direction, and further comprises a respective additional sidewall facing a horizontal direction that is different from the first outward surface normal direction (which may be parallel, antiparallel, or perpendicular to the first horizontal direction hd1 or the second horizontal direction hd2) and is physically exposed to a surrounding gaseous environment. Examples of such configurations are illustrated in FIG. 17A-17C and 18A-18C.

Referring to FIG. 17A-17C and 18A-18C, regions of fifth, sixth, seventh, eighth, ninth, tenth, eleventh, and twelfth configurations of the embodiment structure are sequentially illustrated during the processing steps of FIG. 10-12. As discussed above, multiple configurations of the phase change memory cells 50 may be provided in different device regions in a same embodiment structure. In an illustrative example, the fifth configuration of the embodiment structure illustrated in FIG. 17A-17C may be formed in a fifth device region R5 of the embodiment structure; the sixth configuration of the embodiment structure illustrated in FIG. 17A-17C may be formed in a sixth device region R6 of the embodiment structure; the seventh configuration of the embodiment structure illustrated in FIG. 17A-17C may be formed in a seventh device region R7 of the embodiment structure; and the eighth configuration of the embodiment structure illustrated in FIG. 17A-17C may be formed in an eighth device region R8 of the embodiment structure. Further, the ninth configuration of the embodiment structure illustrated in FIG. 18A-18C may be formed in a ninth device region R9 of the embodiment structure; the tenth configuration of the embodiment structure illustrated in FIG. 18A-18C may be formed in a tenth device region R10 of the embodiment structure; the eleventh configuration of the embodiment structure illustrated in FIG. 18A-18C may be formed in an eleventh device region R11 of the embodiment structure; and the twelfth configuration of the embodiment structure illustrated in FIG. 18A-18C may be formed in a twelfth device region R12 of the embodiment structure.

FIGS. 17A and 18A correspond to the processing steps described with reference to FIG. 10. FIGS. 17B and 18B correspond to the processing steps described with reference to FIG. 11. FIGS. 17C and 18C correspond to the processing steps described with reference to FIG. 12.

Generally, the phase change memory cells 50 illustrated in FIGS. 17C and 18C are configured to generate a temperature gradient TG along a lateral direction. As used herein, a temperature gradient refers to a non-zero rate of change of temperature with respect to spatial position along a specific direction. In the context of the present disclosure, the temperature gradient along a lateral direction denotes the variation in temperature per unit distance measured along the lateral direction. The direction of the temperature gradient is defined as the direction along which magnitude of the spatial temperature change is mot positive.

In one embodiment, each phase change material portion 54 may be patterned with at least one sidewall that is entirely physically exposed to a surrounding gaseous or vacuum environment upon completion of the anisotropic etch process at the processing steps of FIG. 11. Asymmetry in thermal conductivity is inherently present between a side of each phase change material portion 54 in direct contact with a sidewall liner 58 and another side of each phase change material portion 54 having a physically exposed sidewall. The temperature gradient TG that is generated from the phase change memory cell 50 is generally along the direction from the side having a physically exposed sidewall to the side having a sidewall liner 58. If more than one sidewall of a phase change material portion 54 is physically exposed and/or if more than one sidewall of the phase change material portion 54 is in contact with a sidewall liner 58, the direction of the temperature gradient TG depends on the geometry and may be generally along a direction from a first lateral orientation without the sidewall liner 58 to a second lateral orientation with the sidewall liner 58.

In one embodiment, a first subset of the phase change memory cells 50 is configured to generate a first temperature gradient TG along a first lateral direction. In one embodiment, the first lateral direction is rotated from a first horizontal direction hd1 in a clockwise direction by a first azimuthal angle α1 in a top-down view. As discussed above, the first horizontal direction hd1 may be parallel to a subset of the sidewalls of the phase change material portions 54, and/or along a direction of periodicity of the phase change memory cells 50. In one embodiment, a second subset of the phase change memory cells 50 is configured to generate a second temperature gradient TG along a second lateral direction that is rotated from the first horizontal direction hd1 in the clockwise direction by a second azimuthal angle α2 in the top-down view, the second azimuthal angle α2 being different from the first azimuthal angle α1.

In the example illustrated in FIGS. 17C and 18C, the phase change memory cells 50 in the fifth device region R5, a subset of the phase change memory cells 50 in the ninth device region R9, and a subset of the phase change memory cells 50 in the tenth device region R10 are configured to generate the first temperature gradient TG along a first lateral direction, which is rotated from the first horizontal direction hd1 in the clockwise direction by a first azimuthal angle α1 in a top-down view. The phase change memory cells 50 in the sixth device region R6, a subset of the phase change memory cells 50 in the ninth device region R9, and a subset of the phase change memory cells 50 in the twelfth device region R12 are configured to generate the second temperature gradient TG along a second lateral direction, which is rotated from the first horizontal direction hd1 in the clockwise direction by a second azimuthal angle α2 in the top-down view. The phase change memory cells 50 in the seventh device region R7, a subset of the phase change memory cells 50 in the eleventh device region R11, and a subset of the phase change memory cells 50 in the twelfth device region R12 are configured to generate the second temperature gradient TG along a third lateral direction, which is rotated from the first horizontal direction hd1 in the clockwise direction by a third azimuthal angle α3 in the top-down view. The phase change memory cells 50 in the eighth device region R8, a subset of the phase change memory cells 50 in the tenth device region R10, and a subset of the phase change memory cells 50 in the eleventh device region R11 are configured to generate a fourth temperature gradient TG along a fourth lateral direction, which is rotated from the first horizontal direction hd1 in the clockwise direction by a fourth azimuthal angle α4 in the top-down view. In one embodiment, the second horizontal direction hd2 is perpendicular to the first horizontal direction hd1, and the first lateral direction, the second lateral direction, the third lateral direction, and the fourth lateral direction are not parallel to, and are not perpendicular to, any of the first horizontal direction hd1 and the second horizontal direction hd2.

In one embodiment, phase change material portions 54 within a first subset of the layer stacks (52, 54, 56) comprises a respective sidewall facing a first outward surface normal direction (which may be parallel, antiparallel, or perpendicular to the first horizontal direction hd1 or the second horizontal direction hd2) having a third azimuthal angle with respect to the first horizontal direction hd1 as measured along the clockwise direction. In this embodiment, phase change material portions 54 within a second subset of the layer stacks (52, 54, 56) comprises a respective sidewall facing a second outward surface normal direction having a fourth azimuthal angle with respect to the first horizontal direction hd1 as measured along the clockwise direction and does not comprise any sidewall facing the third horizontal direction. As used herein, an “outward surface normal direction” of a surface refers to a direction that is normal (i.e., perpendicular) to the surface and points outward.

In one embodiment, each sidewall liner 58 in the first subset of the phase change memory cells 50 has a first horizontal cross-sectional shape; and each sidewall liner 58 in the second subset of the phase change memory cells 50 has a second horizontal cross-sectional shape that is not translationally congruent with the first horizontal cross-sectional shape. As used herein, a first two-dimensional shape is translationally congruent with a second two-dimensional shape if the first two-dimensional shape may be positioned to provide a periphery that is identical to the periphery of the second two-dimensional shape only by translation, i.e., without rotation, reflection, or any scaling in size. A first two-dimensional shape is not translationally congruent with a second two-dimensional shape in instances in which the first two-dimensional shape may not be positioned to provide a periphery that is identical to the periphery of the second two-dimensional shape only by translation.

In the illustrated example, sidewall liners 58 in the fifth device region R5 are not translationally congruent with any of the sidewall liners 58 in the sixth device region R6, in the seventh device region R7, or in the eighth device region R8. Further, each of the ninth device region R9, the tenth device region R10, the eleventh device region R11, and the twelfth device region R12 comprises respective first-type sidewall liners 58 that are not translationally congruent with respective second-type sidewall liners 58.

In one embodiment, each of the phase change memory cells 50 comprises a respective phase change material portion 54 that is formed with a sidewall that is parallel to a first horizontal direction hd1. In one embodiment, the second horizontal cross-sectional shape is mirror-symmetric with the first horizontal cross-sectional shape about a vertical plane that is parallel to, or perpendicular to, the first horizontal direction hd1. As used herein, a first two-dimensional shape is mirror-symmetric with a second two-dimensional shape if the second two-dimensional shape is a mirror image of any shape that may be derived through translation from the first two-dimensional shape without any rotation or scaling of the first two-dimensional shape. For example, each of the ninth device region R9 and the tenth device region R10 comprises first-type sidewall liners 58 having a respective first horizontal cross-sectional shape, and second-type sidewall liners 58 having a respective second horizontal cross-sectional shape that is mirror-symmetric with the first horizontal cross-sectional shapes.

In one embodiment, the second horizontal cross-sectional shape is rotationally congruent with the first horizontal cross-sectional shape upon rotation about a vertical direction. As used herein, a first two-dimensional shape is rotationally congruent with a second two-dimensional shape if the second two-dimensional shape may be obtained by translation and rotation of the first two-dimensional shape without any mirroring or scaling. For example, each of the eleventh device region R11 and the twelfth device region R12 comprises first-type sidewall liners 58 having a respective first horizontal cross-sectional shape, and second-type sidewall liners 58 having a respective second horizontal cross-sectional shape that is rotationally congruent with the first horizontal cross-sectional shapes.

In one embodiment, the first subset of the phase change memory cells 50 comprises rows of first-type phase change memory cells 50. Each row of first-type phase change memory cells 50 comprises a respective subset of the first-type phase change memory cells 50 arranged along a second horizontal direction hd2 that is different from the first horizontal direction hd1. In one embodiment, the second subset of the phase change memory cells 50 comprises rows of second-type phase change memory cells 50. each row of second-type phase change memory cells 50 comprises a respective subset of the second-type phase change memory cells 50 arranged along the second horizontal direction hd2. The rows of the first-type phase change memory cells 50 and the rows of the second-type memory cells alternate along the first horizontal direction hd1 as illustrated in the ninth region R9, the tenth region R10, the eleventh region R11, and the twelfth region R12 in FIG. 18C.

In one embodiment, phase change material portions 54 within a first subset of the layer stacks (52, 54, 56) comprises a respective sidewall facing a first outward surface normal direction (which may be parallel or antiparallel to the first horizontal direction, or may be parallel or antiparallel to the second horizonal direction) having an azimuthal angle (which may be an integer multiple of π/2, e.g., 0, π/2, π, or 3π/2) with respect to a first horizontal direction hd1 as measured along a clockwise direction. In one embodiment, the phase change material portions 54 within the first subset of the layer stacks (52, 54, 56) further comprises a respective additional sidewall facing a horizontal direction that is different from the first outward surface normal direction and is physically exposed to a gaseous ambient, i.e., is not in direct contact with any solid phase material portion after the processing steps described with reference to FIG. 12. All such physically exposed surfaces may directly contact an encapsulation dielectric layer to be subsequently deposited.

In one embodiment, additional phase change material portions 54 within a second subset of the layer stacks (52, 54, 56) comprises a respective sidewall facing a second outward surface normal direction (which may be parallel or antiparallel to the first horizontal direction, or may be parallel or antiparallel to the second horizonal direction) having another azimuthal angle with respect to the first horizontal direction hd1 as measured along the clockwise direction and does not comprise any sidewall facing the first horizontal sidewall horizontal direction.

In an illustrative example, phase change material portions 54 within a first subset of the phase change memory cells 50 in the ninth device region R9 may comprise a respective sidewall facing the second horizontal direction hd1 (which is the first outward surface normal direction), and additional phase change material portions 54 within a second subset of the phase change memory cells in the ninth device region R9 may comprise a respective sidewall facing the opposite direction of the second horizontal direction hd2 (which is the second outward surface normal direction). In another illustrative example, phase change material portions 54 within a first subset of the phase change memory cells 50 in the tenth device region R10 may comprise a respective sidewall facing the first horizontal direction hd1 (which is the first outward surface normal direction), and additional phase change material portions 54 within a second subset of the phase change memory cells in the tenth device region R10 may comprise a respective sidewall facing the opposite direction of the first horizontal direction hd1 (which is the second outward surface normal direction).

In one embodiment, the first subset of the layer stacks (52, 54, 56) is configured to generate a first temperature gradient TG along a first lateral direction that is rotated from the first horizontal direction hd1 in the clockwise direction by a first azimuthal angle α1 in a top-down view; and the second subset of the layer stacks (52, 54, 56) is configured to generate a second temperature gradient TG along a second lateral direction that is rotated from the first horizontal direction hd1 in the clockwise direction by a second azimuthal angle α2 in the top-down view, the second azimuthal angle α2 being different from the first azimuthal angle α1.

In one embodiment, each sidewall liner 58 in the first subset of the layer stacks (52, 54, 56) has a first horizontal cross-sectional shape; and each sidewall liner 58 in the second subset of the layer stacks (52, 54, 56) has a second horizontal cross-sectional shape that is not translationally congruent with the first horizontal cross-sectional shape.

FIGS. 19A, 19B, 19C, and 19D are horizontal cross-sectional views thirteenth, fourteenth, fifteenth, and sixteenth configurations of the embodiment structure after the processing steps of FIG. 12. The horizontal cross-sectional views are taken at the level of the phase change material portions 54. Thus, sidewall liners 58 of the phase change memory cells 50 are also illustrated. Keep-out zones (KOZs) are also illustrated, which refer to the region from which heater elements 48 and the bottom electrodes 42 are excluded. In other words, heater elements 48 and bottom electrodes 42 are not present in the keep-out zones. The directions of heat flow during programming operations are indicated by arrows such that the head of the arrow points toward the direction of the heat flow (which is outward and away from the sidewall liners 58). Each phase change material portion 54 comprises a contact region 59, which is a surface portion of the phase change material portion 54 that is in direct contact with the sidewall liner 58.

Referring to FIG. 19A, a thirteenth device region R13 including an array of phase change memory cells 50 having a thirteenth configuration is illustrated. The thirteenth device region R13 may be one of the regions within the embodiment structure of the present disclosure. In the thirteenth configuration, a single sidewall liner 58 laterally encloses a respective phase change material portion 54. In this embodiment, 100 % of the entirety of the sidewalls of each phase change material portion 54 is contacted by a sidewall liner 58.

Referring to FIG. 19B, a fourteenth device region R14 including an array of phase change memory cells 50 having a fourteenth configuration is illustrated. The fourteenth device region R14 may be one of the regions within the embodiment structure of the present disclosure. In the fourteenth configuration, no sidewall liner 58 is provided. Thus, 0 % of the entirety of the sidewalls of each phase change material portion 54 is contacted by a sidewall liner.

Referring to FIG. 19C, a fifteenth device region R15 including an array of phase change memory cells 50 having a fifteenth configuration is illustrated. The fifteenth device region R15 may be one of the regions within the embodiment structure of the present disclosure. In the fifteenth configuration, two sidewall liners 58 may be formed on sidewalls of a phase change material portion 54. The heat flow may be primarily along a first horizontal direction hd1 that is perpendicular to interfaces between the phase change material portion 54 and the sidewall liners 58. The ratio of the total contact area between each phase change material portion 54 and sidewall liners 58 to the total area of the sidewalls of the phase change material portion 54 may be in a range from 0.2 to 0.9, although lesser or greater fractions may also be used.

Referring to FIG. 19D, a sixteenth device region R16 including an array of phase change memory cells 50 having a sixteenth configuration is illustrated. The sixteenth device region R16 may be one of the regions within the embodiment structure of the present disclosure. In the sixteenth configuration, a sidewall liners 58 may be formed on a sidewall of a phase change material portion 54. The heat flow may be unidirectional, and be parallel or antiparallel to a first horizontal direction hd1 that is perpendicular to interfaces between the phase change material portion 54 and the sidewall liners 58. The ratio of the total contact area between each phase change material portion 54 and a sidewall liner 58 to the total area of the sidewalls of the phase change material portion 54 may be in a range from 0.1 to 0.45, although lesser or greater fractions may also be used.

Referring collectively to FIG. 1-19D, in-process layer stacks (52′, 54′, 56′) of a respective in-process bottom liner 52′, a respective in-process phase change material portion 54′, and a respective in-process top electrode 56′ may be formed over a dielectric material layer, and in-process sidewall liners 58′ may be formed on the in-process layer stacks (52′, 54′, 56′). The in-process layer stacks (52′, 54′, 56′) and the in-process sidewall liners 58′ are patterned to form phase change memory cells 50. Patterned portions of the in-process layer stacks (52′, 54′, 56′) comprise layer stacks (52, 54, 56). Patterned portions of the in-process sidewall liners 58′ comprise sidewall liners 58. Phase change memory cells 50 comprising contiguous combination of a respective one of the layer stacks (52, 54, 56) and a respective subset of the sidewall liners 58 are formed. Each of the phase change memory cells 50 comprises a respective layer stack (52, 54, 56) including a bottom liner 52, a phase change material portion 54 comprising a phase change material, and a top electrode 56, and at least one sidewall liner 58 located on at least one sidewall of the layer stack (52, 54, 56). In one embodiment, for each phase change memory cell 50 within a first subset of the phase change memory cells 50, a ratio of a total contact area between the phase change material portion 54 and the at least one sidewall liner 58 to a total sidewall area of the phase change material portion 54 has a value of a first fraction; and for each phase change memory cell 50 within a second subset of the phase change memory cells 50, a ratio of a total contact area between the phase change material portion 54 and the at least one sidewall liner 58 to a total sidewall area of the phase change material portion 54 has a value of a second fraction that is different from the first fraction. The direction of stress caused by the heat flow is the same as the direction of the heat flow, and is the same as the temperature gradient caused by the heat flow.

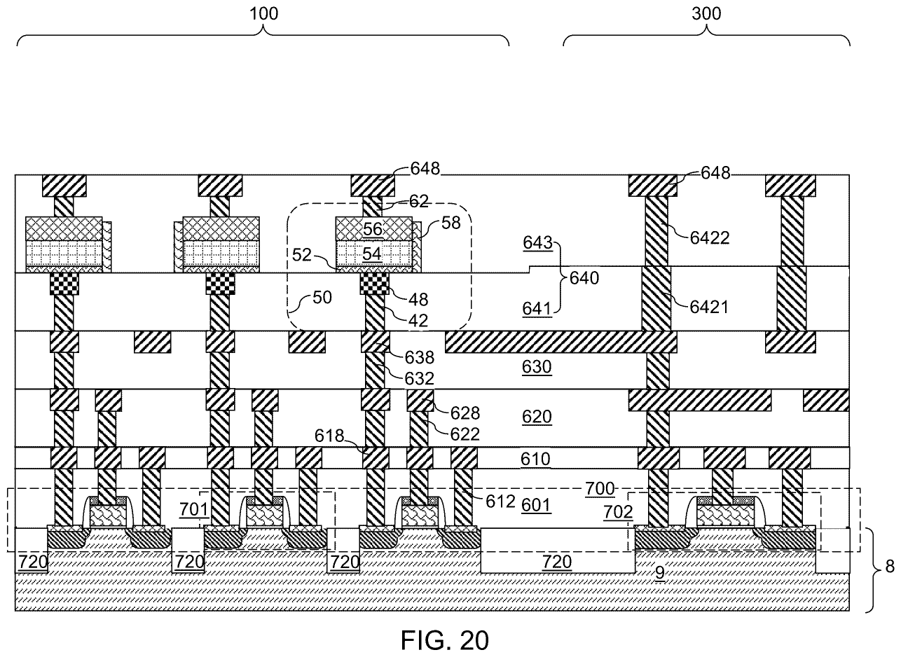

Referring to FIG. 20, an encapsulation dielectric layer 643 and additional metal interconnect structures (62, 6422, 648) may be formed over the phase change memory cells 50. The encapsulation dielectric layer 643 comprises at least one interlayer dielectric material such as silicon oxide, silicon nitride, and/or silicon carbide nitride. The additional metal interconnect structures (62, 6422, 648) may comprise top-contact via structures 62 contacting a top surface of a respective one of the top electrodes 56, upper peripheral via structures 6422 that are formed on lower peripheral via structures 6421, and fourth metal line structures 648 that are formed on the top-contact via structures 62 and the upper peripheral via structures 6422. Top surfaces of the fourth metal line structures 648 may be coplanar with the horizontal top surface of the encapsulation dielectric layer 643. The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed to provide electrical connections between the top electrodes 56 of the phase change memory cells 50 and the various semiconductor devices 700 that underlie the dielectric material layers (601, 610, 620, 630, 640).

Generally, programming transistors 701 may be provided on a substrate 8. Metal interconnect structures (612, 618, 622, 628, 632, 638, 42, 6421) embedded within interconnect-level dielectric material layers (601, 610, 620, 630, 641) may be formed over the programming transistors 701. Bottom electrodes 42 and heater elements 48 may be formed within a dielectric material layer, such as a lower fourth interconnect-level dielectric material layer 641. Each heater element 48 is electrically connected to an electrical node, such as an output node, of a respective programming transistor 701. A continuous layer stack (52L, 54L, 56L) including a bottom liner layer 52L, a phase change material layer 54L comprising a phase change material, and a top electrode material layer 56L may be deposited and patterned to form layer stacks (52, 54, 56) of a bottom liner 52, a phase change material portion 54, and a top electrode 56. A sidewall liner layer 58L may be formed and patterned to form sidewall liners 58. At least one sidewall liner 58 may be formed on at least one sidewall of each layer stack (52, 54, 56).

Each sidewall liner 58 comprises a material having an electrical conductivity that is higher than an electrical conductivity of an amorphous phase of the phase change material of the phase change material portions 54. For each phase change memory cell 50, an encapsulation dielectric layer 643 may be deposited directly on at least one sidewall of the layer stack (52, 54, 56) (which is a patterned portion of the continuous layer stack (52L, 54L, 56L)) and directly on an outer sidewall of each of the at least one sidewall liner 58 and directly on a top surface of the layer stack (52, 54, 56). Thus, for each phase change memory cell 50, the encapsulation dielectric layer 643 is in contact with at least one sidewall of the layer stack, an outer sidewall of each of the at least one sidewall liner 58, and a top surface of the layer stack (52, 54, 56).

For each phase change memory cell 50 that is electrically connected to a programming transistor 701, the programming transistor 701 is configured to program the phase change memory cell 50 into at least three different resistive states by applying at least three different programming pulse patterns to the heater element 48. FIGS. 18A-18D are various configurations of a phase change material portion 54 in various programmed resistance states according to an embodiment of the present disclosure.

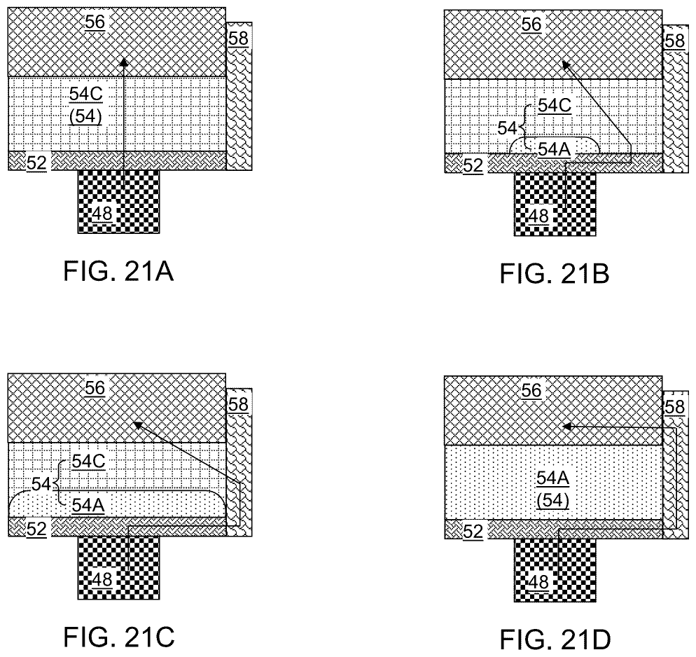

Referring to FIG. 21A, a phase change memory cell 50 in a low resistance state is illustrated. In this embodiment, at least 99 % of the entire volume of the phase change material portion 54 is in a polycrystalline phase. In one embodiment, the entirety of the phase change material portion 54 may be a crystalline phase change material portion 54C including a polycrystalline phase change material. The electrical conductivity of the crystalline phase change material is higher than the electrical conductivity of the materials of the bottom liner 52 and the at least one sidewall liner 58. Thus, the primary electrically conductive path extends vertically between the heater element 48 and the top electrode 56.

Referring to FIG. 21B, a phase change memory cell 50 in a first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is not in direct contact with the at least one sidewall liner 58. The electrical conductivity of the amorphous phase change material is lower than the electrical conductivity of the materials of the bottom liner 52 and the at least one sidewall liner 58. Thus, the primary electrically conductive path extends laterally within the bottom liner 52 underneath the amorphous phase change material portion 54A and extends through the crystalline phase change material portion 54C between a peripheral portion of the bottom liner 52 and the top electrode 56 at an angle relative to the vertical direction.

Referring to FIG. 21C, a phase change memory cell 50 in a second intermediate state providing a higher resistance than the first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is in direct contact with the at least one sidewall liner 58, and does not contact the top electrode 56. The electrical conductivity of the amorphous phase change material is lower than the electrical conductivity of the materials of the bottom liner 52 and the at least one sidewall liner 58. Thus, the primary electrically conductive path extends laterally within the bottom liner 52 underneath the amorphous phase change material portion 54A, extends vertically through a lower portion of each sidewall liner 58, and extends through the crystalline phase change material portion 54C between a middle portion of each sidewall liner 58 and the top electrode 56 at an angle relative to the vertical direction.

Referring to FIG. 21D, a phase change memory cell 50 in a high resistance state is illustrated. In this embodiment, at least 99 % of an entire volume of the phase change material portion 54 is in an amorphous phase.

While four resistive states of a phase change memory cell 50 are illustrated in FIG. 21A-21D, the pulse pattern of the programming pulse from the programming transistor 701 may be pre-programmed to be selected from a plurality of programming pulse patterns that is stored in a programming circuit for the phase change memory cells 50. The total number of pre-programmed pulse patterns may be in a range from 2 to 210, such as from 3 to 28, and/or from 4 to 26. The total number of resistive states that may be programmed in each phase change memory cell 50 may be the same as the total number of pre-programmed pulse patterns. In one embodiment, each programming transistor 701 may be configured to apply at least four different programming pulse patterns to a respective heater element 48. The programming pulses may have a respective duration and/or voltage ramp-down rate to provide a controlled rate of cooling of a molten region of a phase change material portion 54. The duration of the programming pulses may be in a range from 10 nanoseconds to 500 nanoseconds, the longer programming pulses generally corresponding to formation of large crystallized regions of the phase change material portion 54.

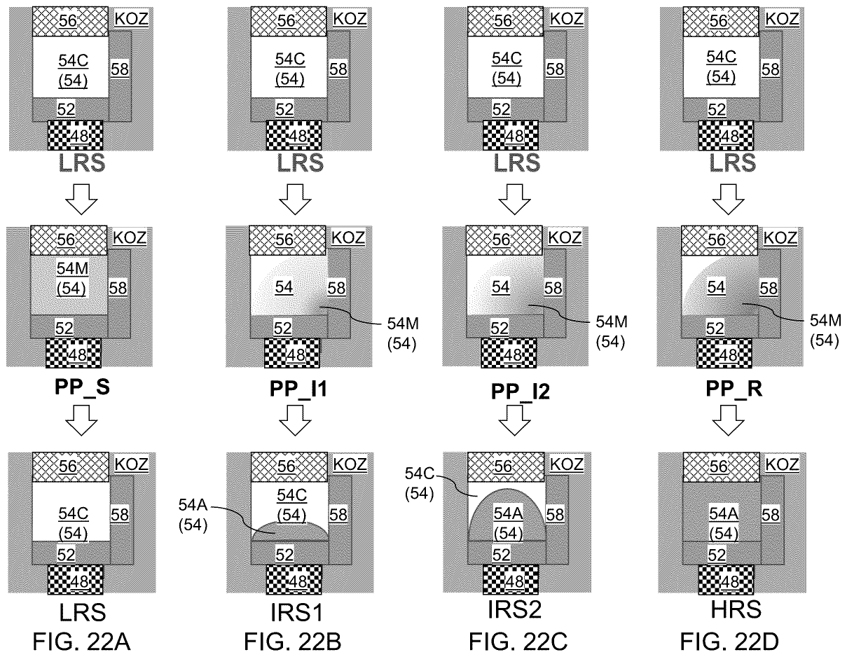

FIG. 22A illustrates sequential vertical cross-sectional views of a phase change memory cell 50 during programing into a low resistance state (LRS). In this illustrative example, an initial state of a phase change memory cell 50 may be a low resistance state, in which the phase change material portion 54 consists of a crystalline phase change material portion 54C. A set programming pulse PP_S may be applied to convert the entirety of the phase change material portion 54 into a molten phase change material portion 54M. The set programming pulse PP_S is slowly ramped down (for example, with a pulse ramp-down time in a range from 10 nanoseconds to 1 microseconds) to induce crystallization of the molten phase change material portion 54M. The entirety of the molten phase change material portion 54M is converted into a crystalline phase change material portion 54C upon completion of the programming operation.

FIG. 22B illustrates sequential vertical cross-sectional views of a phase change memory cell 50 during programing into a first intermediate resistance state (IRS1). In this illustrative example, an initial state of a phase change memory cell 50 may be a low resistance state, in which the phase change material portion 54 consists of a crystalline phase change material portion 54C. A first intermediate programming pulse PP_I1 may be applied to convert a small fraction of the phase change material portion 54 into a molten phase change material portion 54M. The magnitude (i.e., the current and/or the voltage) of the first intermediate programming pulse may be selected to limit the volume of the phase change material portion 54 that is converted into the molten phase change material portion 54M. The first intermediate programming pulse PP_I1 is rapidly terminated (for example, with a pulse ramp-down time less than 1 ns) to induce rapid quenching of the molten phase change material portion 54M. The molten phase change material portion 54M is converted into a small amorphous phase change material portion 54A upon completion of the programming operation. The phase change material portion 54 comprises a combination of the small amorphous phase change material portion 54A and a remnant crystalline phase change material portion 54C.

FIG. 22C illustrates sequential vertical cross-sectional views of a phase change memory cell 50 during programing into a second intermediate resistance state (IRS2). In this illustrative example, an initial state of a phase change memory cell 50 may be a low resistance state, in which the phase change material portion 54 consists of a crystalline phase change material portion 54C. A second intermediate programming pulse PP_I2 may be applied to convert a large fraction of the phase change material portion 54 into a molten phase change material portion 54M. The magnitude (i.e., the current and/or the voltage) of the second intermediate programming pulse may be selected to increase the volume of the phase change material portion 54 that is converted into the molten phase change material portion 54M relative to the volume of the molten phase change material portion 54M that is formed upon application of the first intermediate programming pulse PP_I2. The second intermediate programming pulse PP_I2 is rapidly terminated (for example, with a pulse ramp-down time less than 1 ns) to induce rapid quenching of the molten phase change material portion 54M. The molten phase change material portion 54M is converted into a large amorphous phase change material portion 54A upon completion of the programming operation. The phase change material portion 54 comprises a combination of the large amorphous phase change material portion 54A and a remnant crystalline phase change material portion 54C.

FIG. 22D illustrates sequential vertical cross-sectional views of a phase change memory cell 50 during programing into a high resistance state (HRS). In this illustrative example, an initial state of a phase change memory cell 50 may be a low resistance state, in which the phase change material portion 54 consists of a crystalline phase change material portion 54C. A reset programming pulse PP_I2 may be applied to convert the entirety of the phase change material portion 54 into a molten phase change material portion 54M. The reset programming pulse PP_R is rapidly terminated (for example, with a pulse ramp-down time less than 1 ns) to induce rapid quenching of the molten phase change material portion 54M. The molten phase change material portion 54M is converted into an amorphous phase change material portion 54A, which constitutes the entirety of the phase change material portion 54.

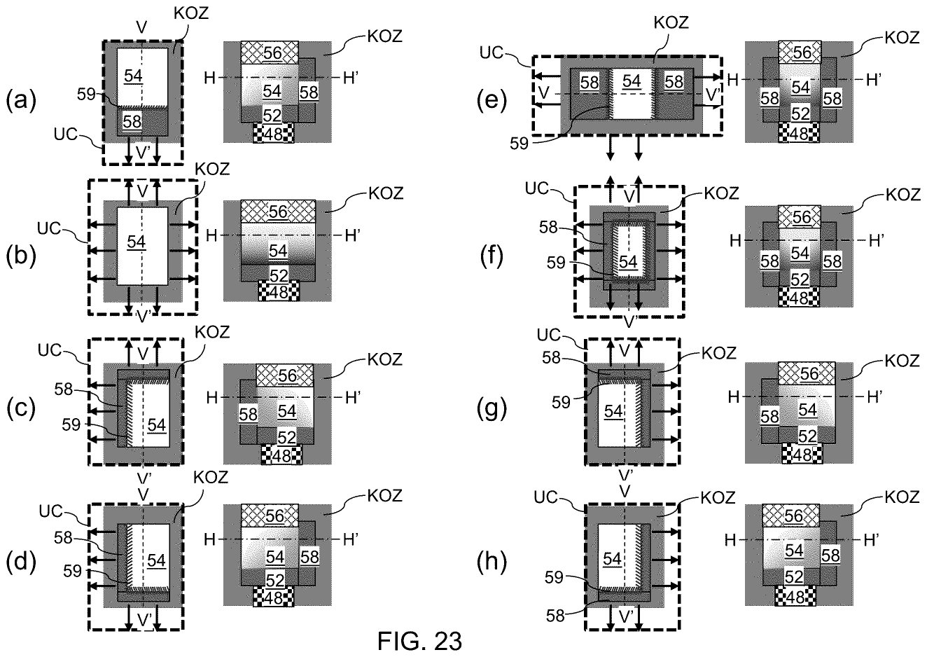

Referring to FIG. 23, various configurations (a), (b), (c), (d), (e), (f), (g), and (h) for a phase change memory cell are illustrated using pairs of a horizontal cross-sectional view and a vertical cross-sectional view. Each vertical cross-sectional view is taken along the vertical plane V-V′ shown in a corresponding horizontal cross-sectional view. Each horizontal cross-sectional view is taken along the horizontal plane H-H′ shown in a corresponding vertical cross-sectional view. Each of the phase change memory cells 50 may function as a repetition unit in a two-dimensional periodic array of phase change memory cells 50. A unit cell UC that function as a unit of repetition in such a two-dimensional periodic array is illustrated for each configuration. Further, a keep-out zone (KOZ) for each configuration is also illustrated. The arrows represent the directions of the heat flow during a programing operation.

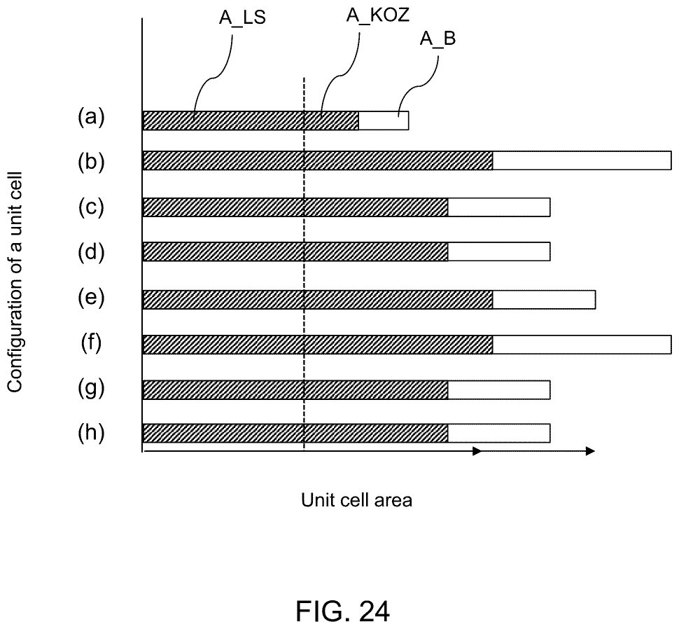

Referring to FIG. 24, a diagram compares the sizes of the unit cell areas of the various configurations of the phase change memory cells 50 illustrated in FIG. 24. The unit cell area may be equal to the sum of a first area A_LS, a second area A_KOZ, and a third area A_B. The first area A_LS is the area of the combination of a layer stack (52, 54, 56) and at least one sidewall liner 58. The second area A_KOZ is the area of the keep-out zone. The third area A_B is a buffer area that is adjacent to the keep-out zone. Presence of additional metal structures (such as metal via structures) in the buffer area is permitted. Generally, a compact design layout with a small buffer area is prone to high thermal stress while providing a high device density, while a relaxed design layout with a larger buffer area reduces thermal stress while providing a low device density.

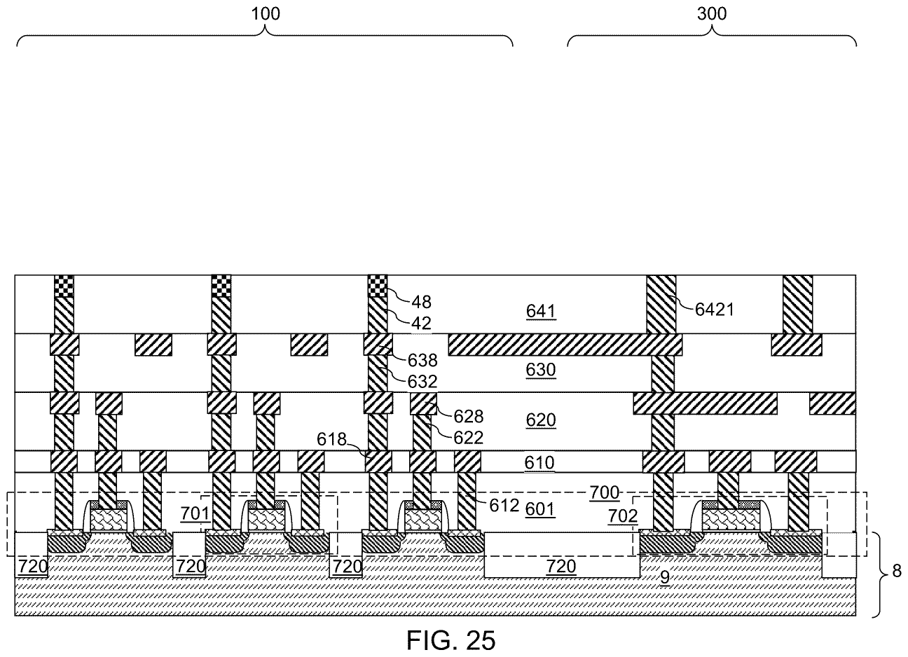

Referring to FIG. 25, a first alternative configuration of the embodiment structure is illustrated after formation of heater elements 48. In the first alternative configuration, the processing steps described with reference to FIG. 5 may be omitted. In this embodiment, each heater element 48 may have the same lateral dimension as a respective underlying bottom electrode 42. The sidewall of each heater element 48 may be vertically coincident with the sidewall of a respective underlying bottom electrode 42, i.e., may be located within a same vertical plane as the sidewall of the respective underlying bottom electrode 42.

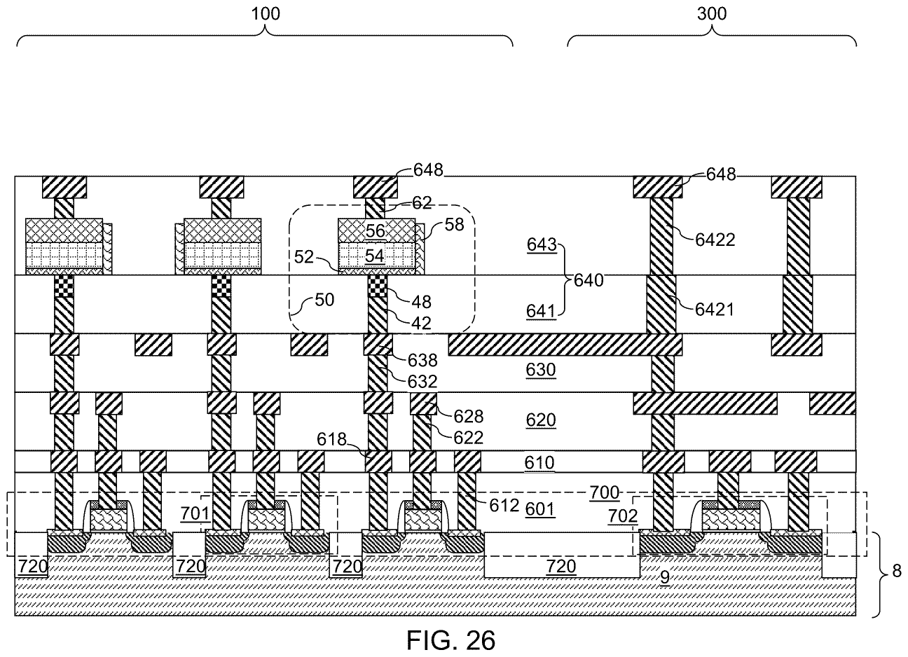

Referring to FIG. 26, the processing steps described with reference to FIGS. 7-20 may be performed on the first alternative configuration of the embodiment structure to provide an array of phase change memory cells 50.

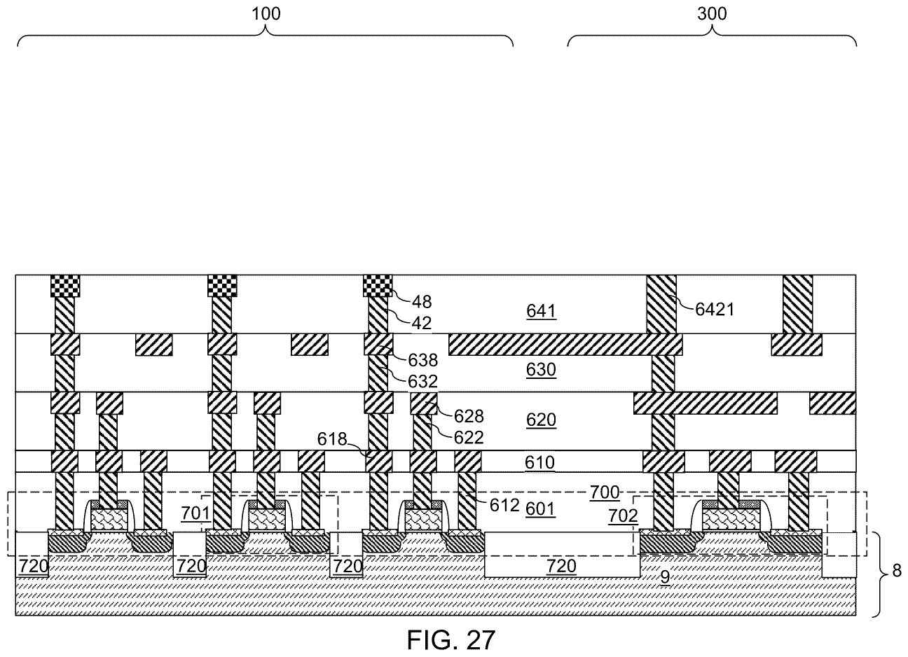

Referring to FIG. 27, the second alternative configuration of the embodiment structure is illustrated, which may be derived from the embodiment structure illustrated in FIG. 6 by using a chemical mechanical polishing process to remove portions of the metallic fill material that overlie the dielectric material layer embedding the bottom electrodes 42. In this embodiment, the entirety of the top surface of the dielectric material layer embedding the bottom electrodes 42 may be formed within a horizontal plane. In other words, the top surface of the dielectric material layer may be formed without any step. The top surfaces of the heater element 48 may be formed within the same horizontal plane as the top surface of the dielectric material layer that embeds the heater elements 48.

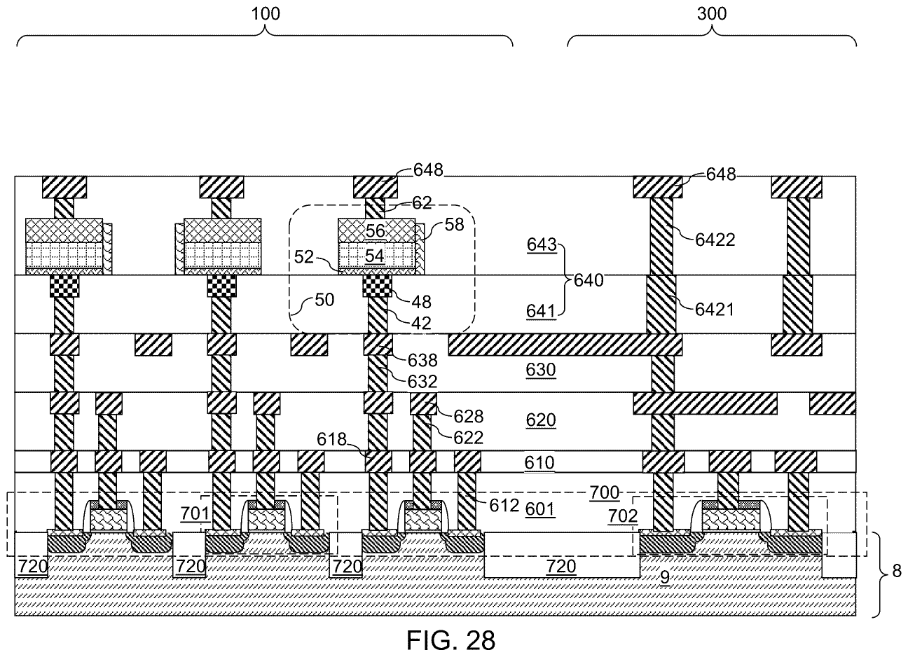

Referring to FIG. 28, the processing steps described with reference to FIGS. 7-17 may be performed on the second alternative configuration of the embodiment structure to provide an array of phase change memory cells 50.

Referring collectively to FIG. 1-28 and according to various embodiments of the present disclosure, a device structure is provided, which comprises phase change memory cells 50, wherein: each of the phase change memory cells 50 comprises a respective layer stack (52, 54, 56) including a bottom liner 52, a phase change material portion 54 comprising a phase change material, and a top electrode 56; and a first subset of the phase change memory cells 50 is configured to generate a first temperature gradient TG along a first lateral direction.

In one embodiment, the first lateral direction is rotated from a first horizontal direction hd1 in a clockwise direction by a first azimuthal angle α1 in a top-down view; and a second subset of the phase change memory cells 50 is configured to generate a second temperature gradient TG along a second lateral direction that is rotated from the first horizontal direction hd1 in the clockwise direction by a second azimuthal angle α2 in the top-down view, the second azimuthal angle α2 being different from the first azimuthal angle α1.

In one embodiment, phase change material portions 54 within a first subset of the layer stacks (52, 54, 56) of the phase change memory cells 50 comprises a respective first sidewall facing a first outward surface normal direction (which may be parallel, antiparallel, or perpendicular to the first horizontal direction hd1 or the second horizontal direction hd2) having a third azimuthal angle with respect to the first horizontal direction hd1 as measured along the clockwise direction; and phase change material portions 54 within a second subset of the layer stacks (52, 54, 56) of the phase change memory cells 50 comprises a respective second sidewall facing a second outward surface normal direction having a fourth azimuthal angle with respect to the first horizontal direction hd1 as measured along the clockwise direction and does not comprise any sidewall facing the third horizontal direction.

In one embodiment, the respective first sidewall is in contact with a respective first sidewall liner 58; the respective second sidewall is in contact with a respective second sidewall liner 58; the bottom liners 52 of the phase change material cells 50 comprise a first electrically conductive material having a first electrical conductivity; and the first sidewall liners 58 and the second sidewall liners 58 of the phase change material cells 50 comprise a second electrically conductive material having a second electrical conductivity that is less than the first electrical conductivity.

In one embodiment, each sidewall liner 58 in the first subset of the phase change memory cells 50 has a first horizontal cross-sectional shape; and each sidewall liner 58 in the second subset of the phase change memory cells 50 has a second horizontal cross-sectional shape that is not translationally congruent with the first horizontal cross-sectional shape. In other words, the second horizontal cross-sectional shape may not be matched to the first horizontal cross-sectional shape by any type of linear translation only along any horizontal direction. The second horizontal cross-sectional shape may, or may not be, rotationally congruent with the first horizontal cross-sectional shape. The second horizontal cross-sectional shape may, or may not be, mirror-symmetric with respect to the first horizontal cross-sectional shape. The second horizontal cross-sectional shape may have a same area as, or may have a different area from, the first horizontal cross-sectional shape.

In some embodiments, a subset of the phase change memory cells 50 may be formed without any sidewall liner 58, for example, as illustrated in configuration (b) in FIG. 23. In this case, the net temperature gradient generated from such phase change memory cells 50 can be zero. In other words, such phase change memory cells 50 may not have any horizontal direction along which net flow of heat can be generated. Such a subset of phase change memory cells 50 not generating any net horizontal heat flow may be formed in a same device structure as at least one set of phase change memory cells 50 each generating a respective horizontal heat flow along a respective horizontal direction.

In one embodiment, the device structure of the present disclosure comprises: a bottom electrode 42 and a heater element 48 embedded within a dielectric material layer; a layer stack (52, 54, 56) including a bottom liner 52, a phase change material portion 54 comprising a phase change material, and a top electrode 56; and at least one sidewall liner 58 located on at least one sidewall of the layer stack and comprising a material having an electrical conductivity that is higher than an electrical conductivity of an amorphous phase of the phase change material.

In one embodiment, the electrical conductivity of the amorphous phase of the phase change material is in a range from 1.0×10⁻⁸ S/cm to 1.0×10⁻³ S/cm; and the electrical conductivity of the sidewall liner 58 material is in a range from 1.0×101 S/cm to 1.0×10⁵ S/cm. In one embodiment, the bottom liner layer 52L comprises a material having an electrical conductivity that is at least 3 times the electrical conductivity of the sidewall liner material. In one embodiment, the device structure comprises an encapsulation dielectric layer 643 in contact with at least one sidewall of the layer stack, an outer sidewall of each of the at least one sidewall liner 58, and a top surface of the layer stack (52, 54, 56).

According to another aspect of the present disclosure, a device structure is provided, which comprises: a programming transistor 701 located on a substrate 8; a bottom electrode 42 and a heater element 48 embedded within a dielectric material layer, wherein the heater element 48 is electrically connected to an electrical node of the programming transistor 701; and a phase change memory cell 50 comprising a layer stack including a bottom liner 52, a phase change material portion 54 comprising a phase change material, and a top electrode 56, and further comprising at least one sidewall liner 58 located on at least one sidewall of the layer stack, wherein the programming transistor 701 is configured to program the phase change memory cell 50 into at least three different resistive states by applying at least three different programming pulse patterns to the heater element 48.

In one embodiment, the at least three different resistive states comprises: a high resistance state in which at least 99 % of an entire volume of the phase change material portion 54 is in an amorphous phase; a low resistance state in which at least 99% of the entire volume of the phase change material portion 54 is in a polycrystalline phase; and a first intermediate state in which the phase change material portion 54 comprises a first volume having the amorphous phase and a second volume having the crystalline phase, the first volume is not in direct contact with the at least one sidewall liner 58, and having a higher resistance than the low resistance state. In one embodiment, the at least three different resistive states further comprise a second intermediate state containing an amorphous volume having the amorphous phase and contacting the bottom liner 52 and the at least one sidewall liner 58 and not contacting the top electrode 56; and the programming transistor 701 is configured to apply at least four different programming pulse patterns to the heater element 48.

In one embodiment, the bottom liner 52 comprises a first metallic nitride material; and the at least one sidewall liner 58 comprises a second metallic nitride material having an electrical conductivity that is less than ⅓ of an electrical conductivity of the first metallic nitride material.

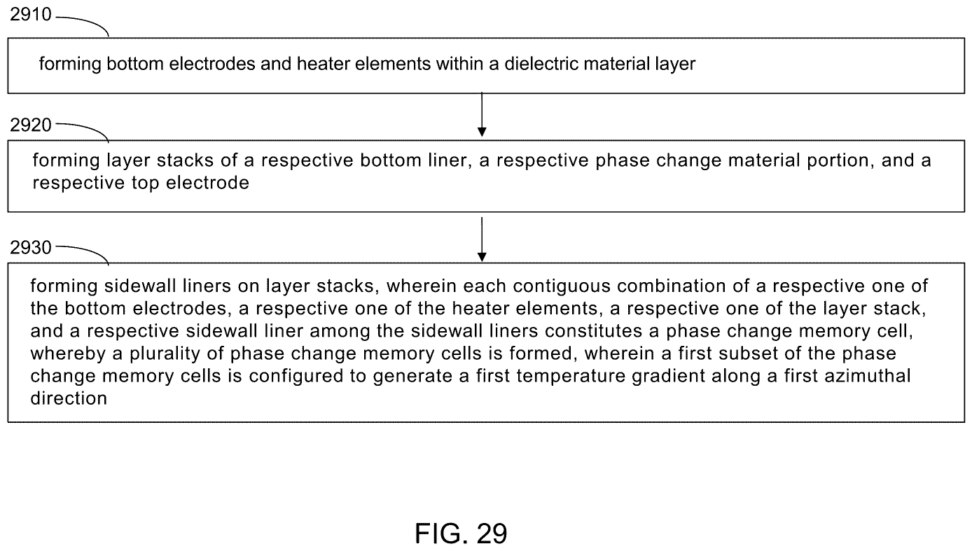

Referring to FIG. 29, a first flow chart for forming a device structure of the present disclosure is illustrated.

Referring to step 2910 and FIG. 1-6, bottom electrodes 42 and heater elements 48 are formed within a dielectric material layer.

Referring to step 2920 and FIG. 7-28, layer stacks (52, 54, 56) of a respective bottom liner 52, a respective phase change material portion 54, and a respective top electrode 56 are formed.

Referring to step 2930 and FIG. 9-28, sidewall liners 58 are formed on layer stacks (52, 54, 56). Each contiguous combination of a respective one of the bottom electrodes 42, a respective one of the heater elements, a respective one of the layer stack (52, 54, 56), and a respective sidewall liner 58 selected from the sidewall liners 58 constitutes a phase change memory cell 50, whereby a plurality of phase change memory cells 50 is formed. A first subset of the phase change memory cells 50 is configured to generate a first temperature gradient TG along a first lateral direction.

In embodiments, the first lateral direction may be rotated from a first horizontal direction in a clockwise direction by a first azimuthal angle in a top-down view; and a second subset of the plurality of phase change memory cells 50 may be configured to generate a second temperature gradient along a second lateral direction that may be rotated from the first horizontal direction in the clockwise direction by a second azimuthal angle in the top-down view, the second azimuthal angle being different from the first azimuthal angle.

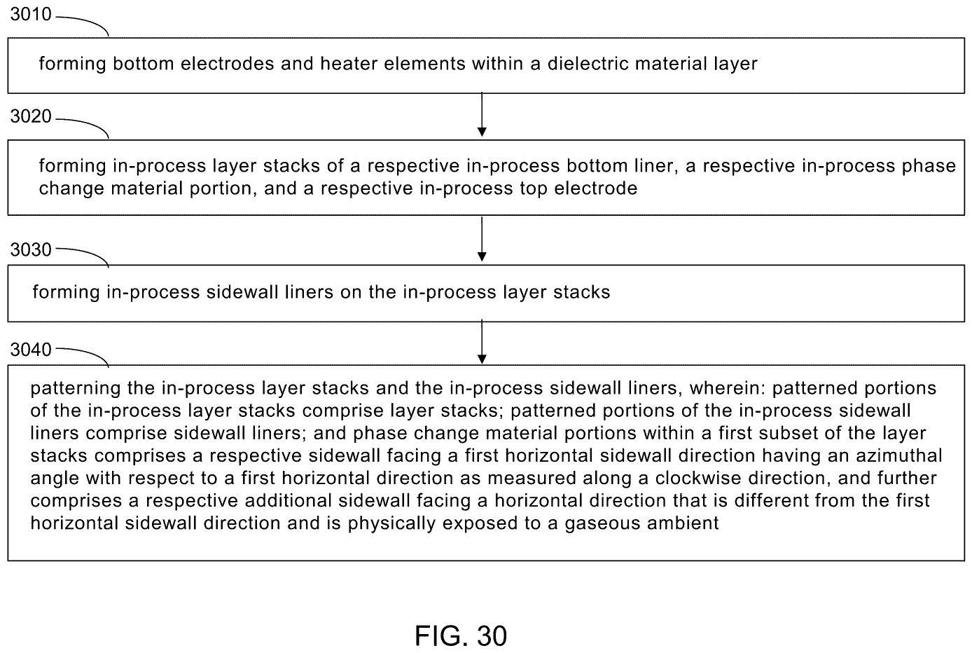

Referring to FIG. 30, a second flow chart for forming a device structure of the present disclosure is illustrated.

Referring to step 3010 and FIG. 1-6, bottom electrodes 42 and heater elements 48 are formed within a dielectric material layer.

Referring to step 3020 and FIGS. 7 and 8, in-process layer stacks (52′, 54′, 56′) of a respective in-process bottom liner 52′, a respective in-process phase change material portion 54′, and a respective in-process top electrode 56′ are formed.

Referring to step 3030 and FIGS. 9 and 10, in-process sidewall liners 58′ are formed on the in-process layer stacks (52′, 54′, 56′).

Referring to step 3040 and FIG. 11-28, the in-process layer stacks (52′, 54′, 56′) and the in-process sidewall liners 58′ are patterned. Patterned portions of the in-process layer stacks (52′, 54′, 56′) comprise layer stacks (52, 54, 56). Patterned portions of the in-process sidewall liners 58′ comprise sidewall liners 58. Phase change material portions 54 within a first subset of the layer stacks (52, 54, 56) comprises a respective sidewall facing a first outward surface normal direction (which may be parallel, antiparallel, or perpendicular to the first horizontal direction hd1 or the second horizontal direction hd2) having an azimuthal angle with respect to a first horizontal direction hd1 as measured along a clockwise direction, and further comprises a respective additional sidewall facing a horizontal direction that is different from the first outward surface normal direction (which may be parallel, antiparallel, or perpendicular to the first horizontal direction hd1 or the second horizontal direction hd2) and is physically exposed to a surrounding gaseous ambient.

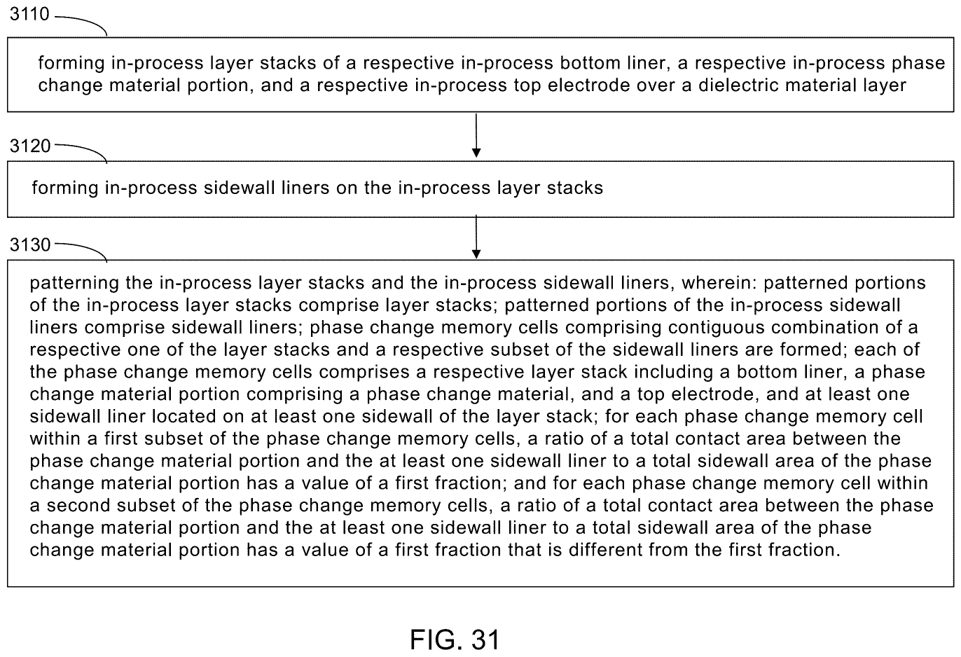

Referring to FIG. 31, a third flow chart for forming a device structure of the present disclosure is illustrated.

Referring to step 3110 and FIG. 1-8, in-process layer stacks (52′, 54′, 56′) of a respective in-process bottom liner 52′, a respective in-process phase change material portion 54′, and a respective in-process top electrode 56′ are formed over a dielectric material layer.

Referring to step 3120 and FIGS. 9 and 10, in-process sidewall liners 58′ are formed on the in-process layer stacks (52′, 54′, 56′).

Referring to step 3130 and FIG. 11-28, the in-process layer stacks (52′, 54′, 56′) and the in-process sidewall liners 58′ are patterned. Patterned portions of the in-process layer stacks (52′, 54′, 56′) comprise layer stacks (52, 54, 56). Patterned portions of the in-process sidewall liners 58′ comprise sidewall liners 58. Phase change memory cells 50 comprising contiguous combination of a respective one of the layer stacks (52, 54, 56) and a respective subset of the sidewall liners 58 are formed. Each of the phase change memory cells 50 comprises a respective layer stack (52, 54, 56) including a bottom liner 52, a phase change material portion 54 comprising a phase change material, and a top electrode 56, and at least one sidewall liner 58 located on at least one sidewall of the layer stack (52, 54, 56). For each phase change memory cell 50 within a first subset of the phase change memory cells 50, a ratio of a total contact area between the phase change material portion 54 and the at least one sidewall liner 58 to a total sidewall area of the phase change material portion 54 has a value of a first fraction. For each phase change memory cell 50 within a second subset of the phase change memory cells 50, a ratio of a total contact area between the phase change material portion 54 and the at least one sidewall liner 58 to a total sidewall area of the phase change material portion 54 has a value of a second fraction that is different from the first fraction.

Embodiments of the present disclosure reduce thermal cross-talk and thermal stress in phase change memory cells 50 while enhancing scalability, efficiency, and reliability. By incorporating sidewall liners 58 configured for directional heat dissipation, embodiments of the present disclosure effectively stabilize resistance in various programmed resistive states and suppress resistance drift. Stabilization of programmed resistance levels allows for accurate representation of programmed states in computation-in-memory applications. Additionally, the ability to implement multiple geometrical configurations of phase change memory cells on a single substrate 8 provides flexibility in thermal management at the array level. For example, multiple phase change memory arrays may include different configurations for the phase change memory cells 50 such that heat flows along different directions, e.g., toward a most proximal periphery of a semiconductor die. The use of materials with tailored electrical conductivities, such as carbon-or nitrogen-doped metallic nitrides, in the sidewall liners 58 further ensures that the resistance of the sidewall liners 58 predominantly determines the resistance of high-resistance states, minimizing the influence of resistance variations inherent to the phase change material. Embodiments of the present disclosure may facilitate different local temperature gradient directions across multiple memory configurations, enabling directional heat dissipation and extended device reliability. The various features of embodiments of the present disclosure collectively provide advantages for modern memory applications, including reduced power consumption, improved reliability, and enhanced scalability.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming bottom electrodes and heater elements within a dielectric material layer;
forming layer stacks of a respective bottom liner, a respective phase change material portion, and a respective top electrode; and
forming sidewall liners on layer stacks, wherein:
each contiguous combination of a respective one of the bottom electrodes, a respective one of the heater elements, a respective one of the layer stack, and a respective sidewall liner selected from the sidewall liners constitutes a phase change memory cell, whereby a plurality of phase change memory cells is formed; and
a first subset of the plurality of phase change memory cells is configured to generate a first temperature gradient along a first lateral direction, wherein:
the first lateral direction is rotated from a first horizontal direction in a clockwise direction by a first azimuthal angle in a top-down view; and
a second subset of the plurality of phase change memory cells is configured to generate a second temperature gradient along a second lateral direction that is rotated from the first horizontal direction in the clockwise direction by a second azimuthal angle in the top-down view, the second azimuthal angle being different from the first azimuthal angle.

2. The method of claim 1, wherein phase change material portions within a first subset of the layer stacks comprises a respective sidewall facing a first outward surface normal direction having a third azimuthal angle with respect to the first horizontal direction as measured along the clockwise direction.

3. The method of claim 2, wherein phase change material portions within a second subset of the layer stacks comprises a respective sidewall facing a second outward surface normal direction having a fourth azimuthal angle with respect to the first horizontal direction as measured along the clockwise direction and does not comprise any sidewall facing a third horizontal direction.

4. The method of claim 1, further comprising:
forming in-process layer stacks on the heater elements, wherein each of the in-process layer stacks comprises a respective in-process bottom liner, a respective in-process phase change material portion and a respective in-process top electrode; and
patterning the in-process layer stacks, wherein patterned portions of the in-process layer stacks comprises the layer stacks.

5. The method of claim 4, further comprising:
forming in-process sidewall liners, wherein each of the in-process sidewall liners is formed around a respective one of the in-process layer stacks; and
patterning the in-process sidewall liners, wherein patterned portions of the in-process sidewall liners comprise the sidewall liners.

6. The method of claim 5, further comprising:
forming a patterned etch mask layer over the in-process layer stacks and over the in-process sidewall liners; and
anisotropically etching portions of the in-process layer stacks and the in-process sidewall liners that are not masked by the patterned etch mask layer, wherein remaining portions of the in-process layer stacks comprise the layer stacks and remaining portions of the in-process sidewall liners comprise the sidewall liners.

7. The method of claim 4, wherein the sidewall liners within the plurality of phase change memory cells are formed by:
depositing a sidewall liner layer on the in-process layer stacks;
anisotropically etching the sidewall liner layer, wherein remaining portions of the sidewall liner layer comprise in-process sidewall liners; and
patterning the in-process sidewall liners into the sidewall liners.

8. The method of claim 7, further comprising performing an anisotropic etch process using an etch mask layer that partially covers the in-process layer stacks and the in-process sidewall liners as an etch mask, wherein each of the layer stack comprises a patterned portion of a respective one of the in-process layer stacks and comprises a respective phase change material portion having at least one sidewall that is entirely physically exposed to a surrounding gaseous or vacuum environment upon completion of the anisotropic etch process.

9. The method of claim 2, wherein:
each sidewall liner in the first subset of the plurality of phase change memory cells has a first horizontal cross-sectional shape; and
each sidewall liner in the second subset of the plurality of phase change memory cells has a second horizontal cross-sectional shape that is not translationally congruent with the first horizontal cross-sectional shape.

10. The method of claim 9, wherein:
each of the plurality of phase change memory cells comprises a respective phase change material portion that is formed with a sidewall that is parallel to a first horizontal direction; and
the second horizontal cross-sectional shape is mirror-symmetric with the first horizontal cross-sectional shape about a vertical plane that is parallel to, or perpendicular to, the first horizontal direction.

11. The method of claim 9, wherein the second horizontal cross-sectional shape is rotationally congruent with the first horizontal cross-sectional shape upon rotation about a vertical direction.

12. The method of claim 9, wherein:
the first subset of the plurality of phase change memory cells comprises rows of first-type phase change memory cells, wherein each row of first-type phase change memory cells comprises a respective subset of the first-type phase change memory cells arranged along a second horizontal direction that is different from the first horizontal direction;
the second subset of the plurality of phase change memory cells comprises rows of second-type phase change memory cells, wherein each row of second-type phase change memory cells comprises a respective subset of the second-type phase change memory cells arranged along the second horizontal direction; and
the rows of the first-type phase change memory cells and the rows of the second-type memory cells alternate along the first horizontal direction.

13. A method of forming a device structure, comprising:
forming bottom electrodes and heater elements within a dielectric material layer;
forming in-process layer stacks of a respective in-process bottom liner, a respective in-process phase change material portion, and a respective in-process top electrode;
forming in-process sidewall liners on the in-process layer stacks; and
patterning the in-process layer stacks and the in-process sidewall liners, wherein:
patterned portions of the in-process layer stacks comprise layer stacks;
patterned portions of the in-process sidewall liners comprise sidewall liners; and
phase change material portions within a first subset of the layer stacks comprises a respective sidewall facing a first outward surface normal direction having an azimuthal angle with respect to a first horizontal direction as measured along a clockwise direction, and further comprises a respective additional sidewall facing a horizontal direction that is different from the first outward surface normal direction and is physically exposed to a surrounding gaseous environment.

14. The method of claim 13, wherein additional phase change material portions within a second subset of the layer stacks comprises a respective sidewall facing a second outward surface normal direction having another azimuthal angle with respect to the first horizontal direction as measured along the clockwise direction and does not comprise any sidewall facing the first horizontal sidewall horizontal direction.

15. The method of claim 14, wherein:
the first subset of the layer stacks is configured to generate a first temperature gradient along a first lateral direction that is rotated from the first horizontal direction in the clockwise direction by a first azimuthal angle in a top-down view; and
the second subset of the layer stacks is configured to generate a second temperature gradient along a second lateral direction that is rotated from the first horizontal direction in the clockwise direction by a second azimuthal angle in the top-down view, the second azimuthal angle being different from the first azimuthal angle.

16. The method of claim 14, wherein:
each sidewall liner in the first subset of the layer stacks has a first horizontal cross-sectional shape; and
each sidewall liner in the second subset of the layer stacks has a second horizontal cross-sectional shape that is not translationally congruent with the first horizontal cross-sectional shape.

17. A device structure comprising:
phase change memory cells, wherein:
each of the phase change memory cells comprises a respective layer stack including a bottom liner, a phase change material portion comprising a phase change material, and a top electrode;
a first subset of the phase change memory cells is configured to generate a first temperature gradient along a first lateral direction that is rotated from a first horizontal direction in a clockwise direction by a first azimuthal angle in a top-down view; and
a second subset of the plurality of phase change memory cells is configured to generate a second temperature gradient along a second lateral direction that is rotated from the first horizontal direction in the clockwise direction by a second azimuthal angle in the top-down view, the second azimuthal angle being different from the first azimuthal angle.

18. The device structure of claim 17, wherein:
each phase change material portion within the first subset of the layer stacks of the phase change memory cells comprises a respective first sidewall facing a first outward surface normal direction having a third azimuthal angle with respect to the first horizontal direction as measured along the clockwise direction; and
each phase change material portions within the second subset of the layer stacks of the phase change memory cells comprises a respective second sidewall facing a second outward surface normal direction having a fourth azimuthal angle with respect to the first horizontal direction as measured along the clockwise direction and does not comprise any sidewall facing a third horizontal direction.

19. The device structure of claim 18, wherein:
the respective first sidewall is in contact with a respective first sidewall liner;
the respective second sidewall is in contact with a respective second sidewall liner;
the bottom liners of the phase change memory cells comprise a first electrically conductive material having a first electrical conductivity; and
the first sidewall liners and the second sidewall liners of the phase change material cells comprise a second electrically conductive material having a second electrical conductivity that is less than the first electrical conductivity.

20. The device structure of claim 19, wherein:
each first sidewall liner in the first subset of the phase change memory cells has a first horizontal cross-sectional shape; and
each second sidewall liner in the second subset of the phase change memory cells has a second horizontal cross-sectional shape that is not translationally congruent with the first horizontal cross-sectional shape.
